(19) United States
(12) Patent Application Publication
(10) Pub. No.: US 2007/0082464 A1
(43) Pub. Date: Apr. 12, 2007

(54) Apparatus for block assembly process

(76) Inventors: Kenneth David Schatz, Los Altos, CA (US); Gordon Craig, Palo Alto, CA (US); Cornelius Sutu, Pittsburg, CA (US); John Stephen Smith, San Jose, CA (US); Samuel L. Robillos, Milpitas, CA (US); Omar Alvarado, Gilroy, CA (US); Ming Chan, Milpitas, CA (US); Steve Merrill Harrington, Cardiff, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/546,109

(22) Filed: Oct. 10, 2006

Related U.S. Application Data
(60) Provisional application No. 60/725,981, filed on Oct. 11, 2005.

(51) Int. Cl. H01L 21/30; H01L 21/46

(52) U.S. Cl. 438/458

(57) ABSTRACT

Apparatuses and methods for improved fluidic self assembly (FSA). An apparatus performing an improved FSA method can include one or more of a block deposition and clearing section, a drying section, a lamination section and an inspection section. In a specific embodiment, each of these sections are connected in series but distinctly separate. The deposition and clearing section can additionally include dispenser nozzles, rolling pins, and a cross-flow jet pump nozzle, as well as other components.

This application claims benefit and priority to provisional application 60/725,981 filed on Oct. 11, 2005. The full disclosure of the provisional publication is incorporated herein in its entirety.

### GOVERNMENT RIGHTS NOTICE

This invention was made with government support under at least one of these contracts with North Dakota State University: subcontract SPP002-04, H94003-04-2-0406 (prime); subcontract 4080, DMEA90-01-C-0009 (prime); subcontract SB004-03, DMEA90-03-3-0303 (prime); and subcontract 5038, DMEA90-02-C-0224 (prime). The government has certain rights to this invention.

### FIELD

The present invention relates generally to the field of fabricating IC-containing devices such as radio-frequency identification tags (RFID), sensors, displays, and other devices that comprise an IC, MEMs device, or other functional element on a plastic substrate, and the process of depositing blocks into block receptor sites. In particular, the present invention relates to the set up of an apparatus used in the fabrication process of depositing blocks into receptor site openings. More specifically, various embodiments of the present invention are related to the process of fluidic self-assembly (FSA), and generally, the assembly of Radio Frequency Identification Devices or tags (RFID).

### BACKGROUND

Many industrial and commercial electronic devices depend on integrated circuitry (IC) components for their functionalities. These electronic devices include for example, radios, audio systems, televisions, telephones, cellular phones, computer systems, computer display monitors, hand held pagers, digital video recorders, digital video disc players, and RFID devices to name a few. As these electronic devices advance to become more complex and as consumer or application demands an overall size reduction of these electronic devices, the drive to miniaturize IC packaging also increases. Microstructures are created in the form of block elements containing functional components in response to the trend of miniaturization.

Many electronic devices further require either a large array of functional components or a cost effective means of manufacturing a large array of functional components. For instance, devices that produce, or detect electromagnetic signals or chemicals or other characteristics often depend highly on a large array of functional components. An example is an active matrix liquid crystal display formed by having a large array of many pixels or sub-pixels which are fabricated on amorphous silicon or polysilicon substrates. The pixels or sub-pixels are formed with an array of electronic elements that can function independent of each other while producing an electromagnetic signal. Another example is the manufacturing of RFID's. Each RFID tag typically consists of a functional block element electrically connected to an antenna. In the fabrication process, functional block elements are deposited into receptor sites in a substrate and further processed and electrically coupled to antennas that are placed on the surface of the substrate. Although each RFID tag is formed from the combination of at least one functional block element and an antenna, the fabrication process of the RFID tags is typically most efficient when tags are manufactured in large quantities through one or more arrays. In both of these examples, the functional block elements are manufactured and subsequently deposited into a substrate forming an array using methods such as fluidic self-assembly (FSA). Another method of forming a substrate for functional block element deposition is also described by pending U.S. patent application Ser. No. 11/159,526 which was filed Jun. 22, 2005 by the inventors Gordon Craig et al. which is entitled “Assembly Comprising Functional Blocks Deposited Therein”. This pending application is hereby incorporated here in by reference.

An example of FSA, entitled “Method for fabricating self-assembling microstructures” by inventors John S. Smith et al, is described in U.S. Pat. No. 5,545,291, which is hereby incorporated herein by reference. In this method, microstructures or block elements are mixed with a fluid such as water, forming a combination referred to as a slurry. The slurry is then dispensed over receptor sites in a substrate. The receptor sites will receive a plurality of blocks and the blocks are then subsequently electrically coupled to form electronic assemblies. FSA is a form of random placement and it has proven to be more efficient than any deterministic approach such as pick and place or the use of human or robot arm to pick each element and places it into a corresponding location in a different substrate. Random placement is generally more effective and produces a higher yield when the proper matching shape of block and receptor is used as compared to the pick and place methods when applied to small and abundant elements such as those needed to form large arrays. This process also gives the benefit of fabricating individual blocks from one substrate, each containing a functional component, then assembling the blocks into a separate substrate through FSA.

A random placement method such as FSA has inherent challenges. For example, the stochastic nature of block orientation during placement into openings affects the filling efficiency because blocks are required to be in a specific orientation with respect to the substrate receptor site opening for proper coupling to electrical circuit connections. Furthermore, the process has to adequately address excess blocks and or blocks that are improperly placed into the receptor site openings. Excess blocks and improperly placed blocks need to be removed and ideally, reused, such that the cost of FSA would not become prohibitive. Lastly, unfilled openings need to be refilled to increase overall yield. Therefore it is desirable to have a set up with methods and apparatus that can address the problems associated with conventional systems of FSA. Other methods described to improve the efficiency of the FSA process are also described in pending U.S. patent application Ser. No. 11/159,550 which was filed Jun. 22, 2005 by the inventors Gordon Craig et al. and which is entitled “Strap Assembly Comprising Functional Blocks Deposited Thereon And Method Of Making Same”, and another pending U.S. patent application Ser. No. 11/159,574 which was filed Jun. 22, 2005 by the inventors Kenneth Schatz et al. and which is entitled “Creating Recessed Regions In A Substrate and Assemblies Having Such Recessed Regions” and U.S. Pat. No. 6,527,964 entitled “Methods and Apparatus for Improved Flow in Performing Fluidic Self-Assembly” by inventors John Stephen Smith et al. The pending U.S. Patent applications and the issued U.S. Patent are hereby incorporated herein as reference. Furthermore, whereas conventional methods and apparatus of FSA have primarily been designed to support step, stop, and repeat type processing, this invention presents methods and apparatus optimized for highly efficient continuous FSA processing.

### SUMMARY OF THE INVENTION

The present invention approaches the problems associated with the conventional FSA process from the perspective of the fabrication process and equipment. The present invention includes multiple embodiments relating to the methods and apparatus used in the FSA process to improve deposition yield, removal of excess blocks, and recycling of excess blocks and fluid, thereby increasing overall efficiency of the FSA process. These methods and apparatus support and are optimized for continues FSA processing.

An apparatus that carries out a FSA process comprises multiple modules which may include a block deposition and clearing section, a drying section, a lamination section and an inspection section wherein each section is connected in series but distinctly separate from each other.

In one embodiment, a section of an apparatus for depositing blocks into receptor openings includes a dispenser positioned above an area to receive a substrate that is tilted, in a fluid filled container, where the area to receive a substrate forms a non-zero angle between a transverse axis, perpendicular to a longitudinal axis and direction of travel of the substrate, and a horizontal plane, such that one longitudinal edge of the substrate is higher than another longitudinal edge when tilted. The tilted area aims to assist block movement on the substrate surface.

In another embodiment, a substrate travels up or down a slope, or up and down along a serpentine path, as it moves through a section of an apparatus for depositing blocks into receptor openings that includes a dispenser positioned above an area to receive the substrate, in a fluid filled container. This configuration provides FSA performance similar to a system with a transverse substrate tilt and with improved space efficiency and mechanical simplicity.

In another embodiment of the present invention, a section of an apparatus for depositing blocks into receptor openings comprising a dispenser with nozzles to deposit blocks positioned above an area to receive a substrate wherein the dispenser nozzle is submerged below the surface of a fluid. The dispensing of a blocks is believed to be more controlled and lead to less damage to the blocks by minimizing impact forces and friction when it is performed under the medium of a lubricious fluid.

In another embodiment of the present invention, a section of an apparatus for depositing blocks into receptor openings has a FSA dispenser positioned above an area to receive a substrate which has a chuck template that generates circular vibrations, or any other elliptical vibrations in a fluid filled container to further assist block movement on the substrate surface and filling into the block receptor sites.

Yet another embodiment teaches a section of an apparatus for depositing blocks into receptor openings which has a FSA dispenser positioned above an area to receive a substrate that has a chuck template having at least one of dimples and rib template on its surface and openings for vacuum suction in a fluid filled container. This embodiment is particularly useful for compensating inherent manufacturing defects that can appear in substrates and for better transporting the substrate on the chuck template.

Another embodiment teaches a section of an apparatus for depositing blocks into receptor openings having a FSA dispenser positioned above an area to receive a substrate and a compliant rolling pin that rotates over the substrate surface in a direction opposite to movement of the substrate to remove improperly positioned blocks from the receptor openings and the surface of a substrate in a fluid filled container. The soft and compliant material of the rolling pin removes blocks without damaging the blocks while the frictional forces generated on the surface of contact between the rolling pin and the substrate when the rolling pin brushes over the substrate surface helps to maintain surface tension on the substrate.

Another embodiment teaches a section of an apparatus for depositing blocks into receptor openings having a FSA dispenser positioned above an area to receive a substrate and a cross-flow jet pump nozzle spraying FSA fluid across the substrate surface to clear improperly placed blocks from the substrate surface in a fluid filled container. The cross-flow jet pumps function in complement with the clearing rolling pin to actively remove blocks from the substrate surface.

Another configuration of the present invention teaches at least one section of an apparatus for depositing blocks into receptor openings having a FSA dispenser positioned above an area to receive a substrate, a cross-flow jet pump nozzle to clear blocks, and a circulatory system driven by FSA fluid propelled by an ejector jet pump that recycles and replenishes the blocks and the FSA fluid to the dispenser and the cross-flow jet pump nozzle in a fluid filled container. The blocks and the FSA fluid circulation systems are usually separate and at least one ejector jet pump is dedicated to each dispenser and each cross-flow jet pump nozzle to allow independent control of the dispenser rate and FSA fluid flow rate.

Yet another embodiment of the present invention teaches a combination of each of the individual embodiments described above. This combination includes a fluid filled container, dispenser, shuck template, and a rolling pin. It further includes jet pump and a circulatory system. The fluid filled container rotates about a hollow cylindrical collar that provides a conduit for a substrate with openings into other connection portions of a FSA system. The dispenser dispenses a slurry of blocks positioned over the substrate with openings. An area to receive the substrate that can be titled to form a non-zero angle between a transverse axis of the substrate, perpendicular to the longitudinal axis in a direction of travel of the substrate, and a horizontal plane, where one longitudinal edge of the substrate is higher than another longitudinal edge when tilted. The chuck template generates circular vibrations or any other elliptical vibrations. The rolling pin rotates over surface of the substrate, and the cross-flow jet pump removes improperly positioned blocks from the surface of the substrate and the receptor openings. The circulatory system is driven by flowing FSA fluid that is propelled by an ejector jet pump which recycles and replenishes the blocks and the FSA fluid to the dispenser and the cross-flow jet pump nozzle.

### BRIEF DESCRIPTION OF THE DRAWINGS

The present invention is illustrated by way of examples. The invention is not limited to the figures of the accompanying drawings in which like references indicate similar elements. Additionally, the elements are not necessarily drawn to scale.

FIG. 1A shows multiple modules of an apparatus that carries out the FSA process including two block dispensing process chambers, a retrieval chamber, a drying oven, a lamination system, and an inspection system.

FIG. 1B shows a side view of some components inside a block dispensing and clearing process chamber.

FIG. 1C illustrates an alternate embodiment in which there is a non-zero tilt angle between the longitudinal axis of the web and the horizontal plane

FIG. 2A shows the use of a combination of driving rollers and tension rollers to maintain tension on a substrate and to position the substrate over a chuck template.

FIG. 2B shows a combination of tension roller and driving roller used in a retrieval chamber to retrieve a substrate filled with blocks away from the FSA fluid.

FIG. 2C shows a combination of driving roller, free roller and tension roller in winding a laminated substrate with blocks in the receptor openings into a reel.

FIG. 3A shows two block dispensing and clearing process chambers connected in series by a cylindrical collar and where each process chamber can be tilted to adjust its angle with respect to the horizontal plane by rotating about the cylindrical collar.

FIG. 3B shows the path of a substrate entering a block dispensing and clearing process chamber and exiting through the cylindrical collar into a subsequent FSA processing module.

FIG. 3C shows the path of a substrate unwinding from a reel which is level with the horizontal plane moving through a series of rollers into a tilted process chamber and subsequently exiting a tilted chamber which ultimately is winding up in another reel which is level with the horizontal plane.

FIG. 3D shows the substrate exiting a tilted block dispensing and clearing process chamber into a retrieval chamber which is level with a horizontal plane.

FIG. 4A shows a section of a FSA apparatus with a dispenser over a portion of a substrate lying on top of a tilted area that has a non-zero angle between its transverse axis and a horizontal plane.

FIG. 4B shows a side view of the tilted area to receive a substrate with a non-zero angle between its transverse axis and a horizontal plane with one set of legs is longer than another such that one longitudinal edge of the tilted area is higher than another.

FIG. 5 shows a continuous sheet of substrate that unwinds from one reel in one end and winds into another reel at another end as the substrate moves in the longitudinal direction.

FIG. 6A shows a dispenser with four funnel shaped chambers where the blocks are driven from top to exit nozzles of the dispenser by active pressure.

FIG. 6B shows a dispenser with four funnel shaped chambers where the blocks are passively driven from top to exit nozzles of the dispenser by gravity.

FIG. 6C shows a side view of the active dispensers with a shield for the blocks dispensed from the active dispenser.

FIG. 6D shows a side view of the passive dispensers onto a tilted substrate with a shield for the blocks dispensed from the passive dispenser.

FIG. 6E shows both isometric and top views of the core components in one active block dispenser.

FIG. 7A shows a chuck template capable of producing circular or any other elliptical vibrations that also has openings for vacuum suction.

FIG. 7B shows the effects of circular or any other elliptical vibrations on the blocks.

FIG. 7C shows the motor mounted to the bottom of a chuck template to generate circular or any other elliptical vibrations.

FIG. 8A shows a chuck template with parallel rows of vacuum openings lining between rows of dimples.

FIG. 8B shows a chuck template with rows of vacuum openings alternating with parallel rib templates.

FIG. 9A shows a comparison of substrates, one with a flat bottom surface, another defective substrate with bumps on the bottom surface under the receptor openings.

FIG. 9B shows a defective substrate with bumps on the bottom surface under the receptor openings fitting over dimples on a chuck template that has vacuum openings with two different types of vacuum channels.

FIG. 9C shows a defective substrate with bumps on the bottom surface under the receptor openings fitting over rib templates on chuck template that has vacuum openings with two different types of vacuum channels.

FIGS. 9D shows the result of pressing and stretching a defective substrate on a flat surface.

FIG. 10A shows a rolling pin rolling over the substrate surface during block deposition.

FIG. 10B shows the side view of a rolling pin rotating and rolling over a substrate with excess blocks and inverted blocks.

FIGS. 11A through 11D show a rolling pin encountering blocks under different situations and removing those blocks. FIG. 11A shows a rolling pin encountering an inverted block. FIG. 11B shows a rolling pin encountering an improperly placed block that is protruding from the receptor opening. FIG. 11C shows a rolling pin kick out an inverted or improperly placed block in a receptor or on the surface of the substrate.

FIG. 11D shows a rolling pin rolling over a block that has mostly slid into the receptor opening.

FIGS. 12A through 12C show various different views of a cross-flow jet pump nozzle relative to the rolling pin, dispenser unit and substrate. FIG. 12A shows a three dimensional view; FIG. 12B shows a side view; and FIG. 12C shows a top view.

FIG. 13A shows a top view of the direction of a jet stream of FSA fluid from the cross-flow jet pump nozzles to clear blocks from the substrate surface.

FIG. 13B shows a three-dimensional view of FSA fluid emitting from cross-flow jet pumps to clear blocks from the substrate surface into collector tray.

FIG. 13C shows a side view of a cross-flow jet pump spraying a jet stream of FSA fluid to clear blocks from the substrate surface into a collector tray.

FIG. 14 shows a top view of some components in a block dispensing and clearing process chamber and illustrating where the blocks collected from the substrate surface are re-circulated.

FIGS. 15A shows an ejector pump driving the FSA fluid into pumping out fluid from a reservoir.

FIG. 15B shows a circulatory system that utilizes ejector jet pumps to recycle and replenish fluid in a container filled with fluid and for cross-flow jet pumps, using fluid from a reservoir and fluid from the container.

FIG. 15C shows a circulatory system with an ejector jet pump and a filter to circulate fluid collected by vacuum suction from the chuck template.

FIG. 16 shows a block diagram of an exemplary method in which the blocks are dispensed and cleared within a block dispensing and clearing process chamber.

FIG. 17 shows a block diagram of an exemplary method in which the FSA blocks deposited onto the substrate is post-processed

### DETAILED DESCRIPTION

The present invention relates to apparatuses and methods for depositing blocks into receptor openings in substrates. In particular, the apparatuses and methods are in reference to deposition of functional block elements into a web of receptor sites in a receiving substrate via a FSA process. The descriptions and drawings are illustrative of the invention by example and are not to be construed as limiting the invention. Numerous details are described to provide a thorough understanding of the present invention. In certain instances, well-known or conventional details are not described in order to not unnecessarily obscure the present invention in detail.

The present invention relates to the processes of depositing blocks into receptor openings in a substrate by means of FSA and removing excess and improperly placed blocks that either reside on the surface of the substrate or placed into receptor openings by means of FSA. The FSA method of assembling blocks into arrays is often applied in the manufacturing of RFID. However, it should be recognized that the invention has wider applicability and may be used with electromagnetic, signal detectors (e.g. antennas), micro-electromechanical systems or solar cells or chemical sensors. For instance, the invention may be applied to the manufacturing of an active matrix liquid crystal display in the fabrication of an electronic array to deliver precise voltages for the control of liquid crystal cells to create a liquid crystal display.

In the examples of RFID and liquid crystal display fabrication, each of those devices involves a combination of individual elements into a large array, at least during device fabrication. For the fabrication of RFID tags or other integrated circuit (IC) elements, it is more effective to first form the functional or IC elements in a densely packed array then transfer them separately to another substrate array, where the spacing and arrangement of the IC elements in the web configuration can be customized and possibly separated, dependent on its ultimate application. FSA bridges the separate fabrication of functional elements and formation of the target substrate array, by providing a method of combining the two together in a series of steps.

In the example of RFID tags, while each control or functional element is capable of functioning independently of each other, each element electrically couples to an antenna to become RF functional. The functional element, approximately 1 mm on each side, is also the control element of the RFID tag and is to be connected to an antenna that is much larger, approximately several square centimeters in area. Typically, the fabrication of RFID tags will involve formation of the individual functional elements separate from the formation of antennas and receptor openings in a substrate. FSA unifies these two separate manufacturing processes by depositing a large number of functional elements into the pre-formed receptor openings in a substrate.

Although FSA has the advantage of depositing a large number of functional elements into a large number of receptor sites, the method is inexact and random in nature. The process sometimes results in improperly placed blocks and unfilled receptor openings, resulting in low yield thus becoming a rate-limiting step for the overall manufacturing process.

The present invention in its various embodiments relates to methods and apparatus to improve the efficiency of the FSA process. Various novel elements of the FSA apparatus are presented to promote more efficient filling and removal of excess blocks to increase the overall rate of the filling process. The invention in this application can be used in combination with blocks and receptor openings of all shapes, forms and sizes, including functional block elements containing electrical circuitry and specifically may contain metal and dielectric stack on top of the block. The apparatus and methods can generally be combined with other methods intended to improve the efficiency of the FSA deposition process, such as modification of the receptor site openings or the blocks itself.

The fundamental elements of a FSA system include a dispenser and a substrate with receptor openings. The former dispenses a mixture of blocks and a fluid, known as a slurry, over the recessed regions of the substrate. The embodiments in this application involve other elements of a FSA system to improve the interaction of these two fundamental elements.

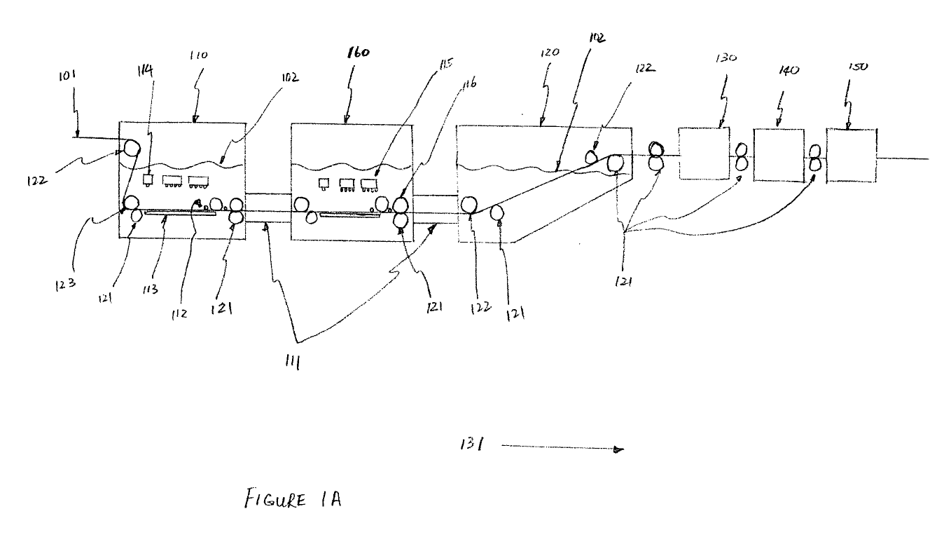

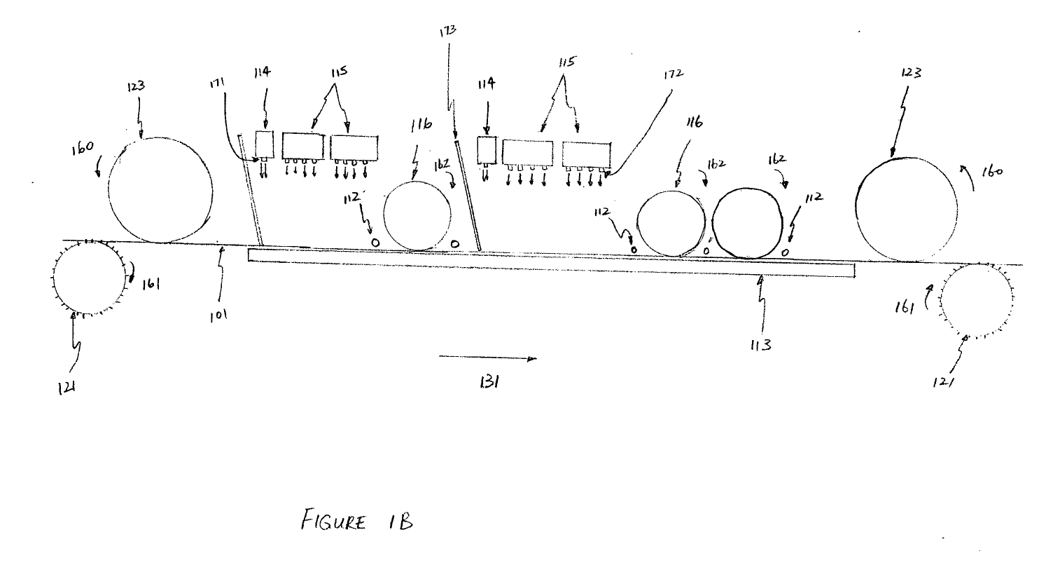

FIG. 1A illustrates multiple modules of an apparatus that carries out the FSA process and post-FSA processes. These modules in the current FSA system include a block dispensing and clearing process chamber, a retrieval chamber, a drying oven, a lamination system, and an inspection system. FSA process begins with a substrate 101 that has receptor openings on the substrate surface to receive blocks. The substrate 101 unwinds from a reel and passes through a number of rollers, a corona discharge surface treatment system, and mid-sonic and ultrasonic substrate cleaning tanks (not shown in this figure) before entering the first FSA process chamber 110, with block dispensing, chuck template, and clearing hardware. Since FSA is a random process, a block deposition and clearing can be repeated each process chamber, and pass through more than one block dispensing and clearing process chamber, such as a second FSA process chamber 160, to enhance fill yield. Furthermore, FSA process can take place under multiple conditions such as being entirely submerged in FSA fluid, partially submerged in FSA fluid, or not submerged in FSA fluid at all. In one embodiment, the block dispensing and clearing process is entirely submerged under the FSA fluid 102. Once blocks are deposited into the receptor openings of the substrate in the block dispensing and clearing process chamber, the substrate is transferred into a retrieval chamber 120 and out of the FSA fluid 102 into a drying oven 130 where the FSA fluid is evaporated and the substrate is dried. A layer of dielectric film, such as polyimide, polyether imide, or polyethylene naphthalate with an thin adhesive layer, is laminated over the substrate surface inside the laminator 140 to secure the blocks inside the receptor openings of the substrate, and further inspected by the inspection system 150 before it is wound onto another reel to complete the process.

During the FSA process and the post-FSA process, the substrate is driven through the various modules by a series of rollers in the direction of the arrow 131. In one embodiment, there are at least four different kinds of rollers, driving rollers 121, free rollers 122, tension rollers 123, and clearing rollers 116. As described by their names, the purpose of the driving rollers 121 is to propel and drive the substrate forward, in the direction of the arrow 131. All driving rollers are actively powered, frequently by a motor, with teeth or gear-like protrusions around the circumference of the roller surface near each edge of the roller. The teeth, sprockets, or gear-like protrusions on each edge of the driving roller fits into a track of openings, sprocket holes, along the edges of the substrate and the driving roller rotates, thereby driving the substrate forward. Driving rollers without teeth or sprockets can also be employed, as can substrate without sprocket holes. In the absence of sprockets, free rollers are located on the opposite side of the substrate from each driving roller, pinching the substrate 101 between the pair of rollers. The driving rollers control the speed of the substrate 101. The free rollers 122 are passive and can freely rotate about its axis of rotation and may or may not have teeth or gear-like protrusions like the driving rollers. The free rollers are to assist the substrate to change directions or simply to provide support. The tension rollers (123) are like the free rollers except their positions can be adjusted to control the tension of the substrate. The tension rollers adjust the tension of the substrate and control the speed of the substrate along each section through various modules along each FSA and post-FSA process. Rollers that contact the top surface of the substrate can have a constant cross-section or can have a periodically varying cross-section such that the roller only contacts the substrate in areas away from receptor sites.

Returning to FIG. 1A, the substrate 101 enters into the first of two block dispensing and clearing process chambers 110 from near the top of the chamber, above the level of the FSA fluid 102, wraps around a free roller 122, submerges under the surface of the FSA fluid 102, wraps around a tension roller 123 over a driving roller 121 and travel over a chuck template 113 that receives the substrate. A slurry of blocks, consisting of FSA fluid and blocks, are deposited from the active dispenser 114 and the passive dispensers 115 onto the substrate 101. The blocks to receptor site openings ratio varies, but can range from approximately 2:1 to approximately 50:1. Typically, the most common block to receptor site opening ratio is approximately from about 5:1 to about 30:1. The excess and improperly positioned blocks are removed from the substrate surface and the receptor site openings by clearing rollers 116 and cross-flow jet pumps 112. The substrate travels from the first process chamber into the second block dispensing and clearing process chamber via a cylindrical collar 111 that connects the process chambers. After the dispensing and clearing processes, the substrate travels through yet another cylindrical collar 111 into a retrieval chamber 120, wraps around another free roller 122 and propels by a driving roller 121 up an incline to above the FSA fluid 102 before changing direction and driven into the drying oven 130 by a driving roller 121. After the FSA fluid has evaporated from the substrate, it travels into a lamination system 140 where a layer of dielectric film is laminated over the substrate to secure the blocks into the receptor site openings. The substrate then enters the inspection system 150 for inspection before it is wound up onto another reel. The driving rollers, tension rollers and free rollers used in this embodiment are interchangeable and can be placed at different positions, relative to the displayed positions, to achieve the same end effect. Therefore, the rollers are not limited to the placements as described. Further, the number of FSA process chambers is not limited to two, as one or more are acceptable, and more than two can be beneficial.

FIG. 1B shows the side view of most components inside a block dispensing and clearing process chamber. The preferred embodiment includes a non-zero tilt angle between the substrate's transverse axis, which is perpendicular to the substrate's direction of travel or the substrate's longest edge, and the horizontal plane. However, to avoid unnecessarily complicating the illustration, the substrate is drawn without a tilt angle, and is parallel with the horizontal plane instead. The substrate as described in FIG. 1A is driven forward in the direction of arrow 131 by the driving rollers 121 with the tension of the substrate adjusted by the tension rollers 123 placed between the driving rollers 121 and the chuck template 113. Typically within each block dispensing and clearing process chamber are two block dispensing and clearing sections. Each section may include an active dispenser 114, two passive dispensers 115, at least one clearing roller 116, at least one cross-flow jet pump nozzle 112, and optionally, a shield 117. There may be one shield associated with each dispenser to prevent blocks from falling beyond the edges of the substrate or the area on the substrate to be filled. In another aspect, the active dispenser nozzle 171 in the active dispenser 114 propels the blocks out of the active dispenser nozzle 171 via an active mechanism such as an ejector pump. For example in one embodiment, the slurry of blocks may be dispensed in a cyclonic motion out of the dispenser nozzle and onto the substrate (this is described further later in this disclosure). On the contrary, in a passive block dispenser 115, the passive nozzle 172 does not force the slurry of blocks out of the dispenser, instead, the slurry of blocks passively fall onto the substrate with assistance of gravity. Moreover, it should be noted that the clearing rollers 116 are actively rotating in a direction 162 that is against the continuous movement of the substrate to clear excess blocks from the surface of the substrate or improperly fitted blocks from the receptor site openings in the substrate.

In the present embodiment, all components are intended to be submerged below the surface of the FSA fluid and are fixed relative to the process chamber. In the operation of the block dispensing and clearing process, only the substrate continuously moves and translates with respect to the process chamber and its components. Each block dispensing and clearing process chamber may contain one or more block dispensing and clearing section, the implementation depends on the size of the process chamber, the capacity and dispensing rate of the dispensers and the ability of the clearing components to clear blocks. Typically, a second clearing roller follows the last dispensing and clearing section to ensure that most excess and improperly placed blocks are removed before the substrate is transferred into a subsequent processing module.

While the driving rollers and the tension rollers rotate in the same direction as the substrate movement, the clearing rollers rotates in an opposition direction of the substrate movement at the point of contact. The clearing roller acts as a brush, in conjunction with the jet stream of FSA fluid ejected from the cross-flow jet pump nozzle 112 to actively clear improperly positioned blocks from the substrate surface and the receptor site openings. A different form of the current invention can be implemented via a different number of dispensing and clearing components in each section, and multiple sections can be repeated in each process chamber, provided that the number of components and sections can be accommodated by the size of the chamber.

FIG. 1C illustrates an alternate embodiment in which there is a non-zero tilt angle between the longitudinal axis of the web and the horizontal plane. The particular embodiment illustrated has two FSA filling regions, one has the angle 126 between the long axis of the web substrate 101 and the horizontal plane, and the second FSA filling region has the angle 127 between the long axis of the web substrate 101 and the horizontal plane. Note that the angle between the first (leftmost in this figure) chuck template 113 and the horizontal plane is angle 126, and that the angle between the second chuck template 113 and the horizontal plane is angle 127. In this embodiment, typically, the tilt angle between the substrate's transverse axis, which is perpendicular to the substrate's direction of travel or the substrate's longest edge, and the horizontal plane is zero. Furthermore, passive dispensers along the length of the web are not typically employed, as active dispensers 114 located at the beginning of each FSA filling region are generally sufficient. Angles 126 and 127 need not be equal and are typically in the approximate range of about 5 degrees to about 30 degrees. For silicon based Nanoblocks of approximate thickness 80 microns and approximate top dimensions of about 850×850 microns, the angles 126 and 127 are preferentially in the range of about 8 to about 12 degrees. For silicon based Nanoblocks of approximate thickness 60 microns and approximate top dimensions of about 350×350 microns, the angles 126 and 127 are preferentially in the range of about 13 to about 16 degrees.

Referring to FIG. 1C, substrate web 101 enters FSA process chamber 110, having been pulled from an upstream unwind station (not shown) and upstream web corona treatment and cleaning stations (not shown). FSA process chamber 110 is partially filled with FSA fluid 102. The web 101 passes under driven roller 121 and slides over chuck template 113, which is submerged in FSA fluid 102. Positioned above the leading portion of chuck template 113 is active dispenser 114, from which NanoBlock devices, an example of one type of blocks that can be used in this process, are dispensed onto web substrate 101. NanoBlocks are delivered into the active dispensers 114 by a block transport system (not shown in this figure). The web substrate 101 moves in the direction 131. Near the end of chuck template 113, excess NanoBlocks are removed from the surface of the web substrate 101 by cross flow jets 112 and clearing roller 116. The web substrate 101 then passes under process tank tension roller 124 and slides over the second chuck template 113, which is the second FSA filling region. As with the first FSA filling region, NanoBlocks are dispensed onto the web substrate 101 from the active dispenser 114 and excess blocks are removed from the surface of the web by cross flow jets 112 and clearing rollers 116. In the embodiment depicted in FIG. 1C, the second FSA filling region ends with three cross-flow jets 112 and two clearing rollers 116. The number of cross-flow jets and clearing rollers can be increased or decreased as desired to balance clearing performance and space efficiency. Excess Nanoblocks removed from the substrate surface are returned to the active dispensers 114 by the block transport system (not shown in this figure). After the second FSA filling region, the web substrate 101 passes between free rollers 125 and out of the process tank 110. Note that to optimize FSA filling for different size NanoBlocks, the angles 126 and 127 can be changed. When changing angle 126, all FSA process chamber components to the left of process tank tension roller 124, starting from drive roller 121, are pivoted around the axis of process tank tension roller 124. When changing angle 127, all FSA process chamber components to the right of process tank tension roller 124, including free rollers 125, are pivoted around the axis of process tank tension roller 124.

Continuing with FIG. 1C, the web substrate 101 passes out of the FSA fluid 102 and FSA process chamber 110 and over tension roller 123. From there the web is pulled through drying oven 130 by driving rollers 121. After the FSA fluid has evaporated from the substrate, it travels into a lamination system 140 where a layer of dielectric film is laminated over the substrate to secure the blocks into the receptor site openings. The substrate then enters the inspection system 150 for inspection before it is wound up onto another reel (not shown). The driving rollers, tension rollers and free rollers used in this embodiment are interchangeable and can be placed at different positions, relative to the displayed positions, to achieve the same end effect. Therefore, the rollers are not limited to the placements as described. Further, the number of FSA filling regions within the FSA process chamber is not limited to two, as one or more are acceptable, and more than two can be beneficial.

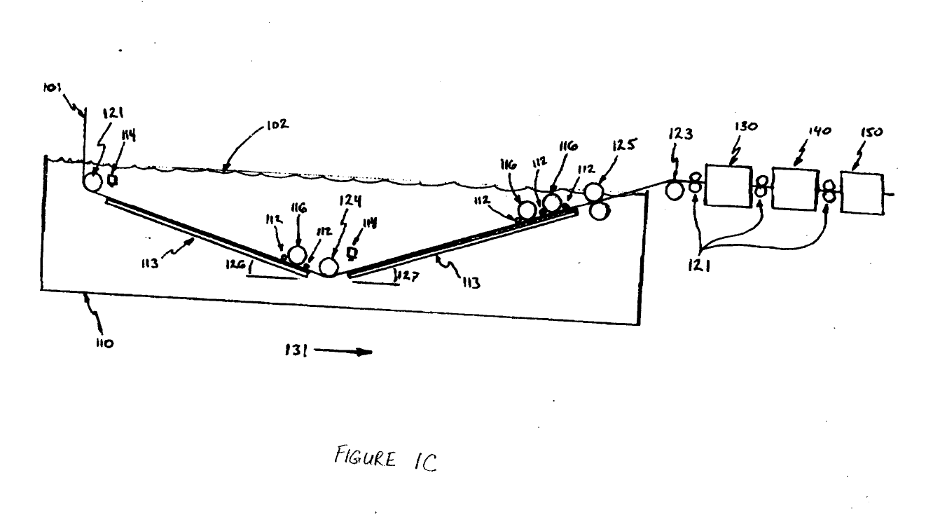

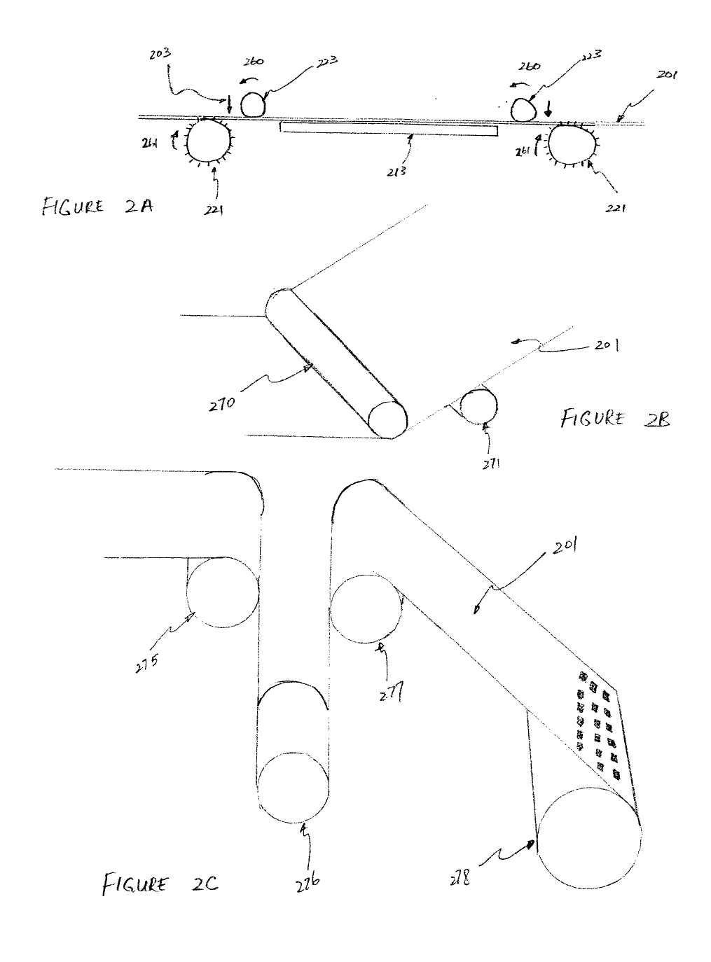

FIG. 2A illustrates the interaction effects of the driving rollers and the tension rollers on the substrate. The tension rollers 223 are positioned between the driving rollers 221 and the chuck template 213. As the tension rollers 223 exert a downward force in the direction of arrow 203, not only is a tension created on the substrate, the substrate is also pressed down onto the chuck template 213. Consequently, the tension rollers 223 also serve to secure the substrate onto the chuck template 213 and complements, and in some cases makes unnecessary, the vacuum suction used to minimize shifting over the chuck template and maximize the transfer of circular or any other elliptical vibrations from the chuck template.

FIG. 2B illustrates the transition of the substrate in the retrieval chamber. The incline up which the substrate travels should not be vertical because of the potential of block loss, and preferably should be in the range of about 10 to about 45 degrees. As the substrate 201 travels up an incline, the roller 270 is used to change direction of the substrate 201. This roller 270 can be a free roller, a tension roller, a driving roller or a combination. Generally, if roller 270 is any one of a free roller, tension roller, or driving roller, there is also a second roller 271 to control the tension or to drive the substrate depending on which function roller 270 serves. The combination of the rollers 270 and 271 and the retrieval chamber is important in that it provides a step to transfer the substrate from a fluid filled environment without having to drain the fluid from the process chambers or otherwise interfere with the dispensing or clearing, while allowing the block dispensing and clearing process to take place entirely under fluid. Dispensing and clearing blocks while submerged in fluid gives the process more control and conserves resources by recycling both the fluid and blocks in one uniform medium.

FIG. 2C illustrates the transfer of the substrate after exiting the inspection module, through a series of roller, winding onto another reel. At this stage, the substrate 201 is filled with blocks in the receptor site openings, dried and laminated. After the inspection module, the series of rollers 275, 276, and 277 serves to adjust the tension and speed of the substrate before winding the substrate onto a reel 278. The rollers 275 and 277 are typically free rollers, but can also be driving rollers or tension rollers. In one embodiment, as the reel 278 is actively winding the substrate by a motor, roller 276 serves as an adjustable tension roller while rollers 275 and 277 serves as fixed, free rollers. In another embodiment, a different roller combination may be used to achieve the same effect in winding the substrate onto the second reel 278. Typically, the reel rotates at such a rate to provide a web speed of approximately at a rate of about 0.3 m/min to about 6 m/min throughout the FSA and post-FSA processing. The speed is generally limited to this range because slower than the lower limit would be too slow and render the entire process inefficient while faster than 6 m/min can result in reduced fill yield. However, if higher speeds are desired, the process chambers can be lengthened to accommodate higher substrate speeds without sacrificing fill yield, as fill yield is dependent on residence time in the process chambers but is independent of substrate speed to speeds over 20 m/min. Nevertheless, the overall filling efficiency of the entire FSA and post-FSA processing is dependent on multiple factors. The traveling speed of the substrate, the blocks to receptor openings ratio, and the shapes of the blocks and receptors are only some of the factors.

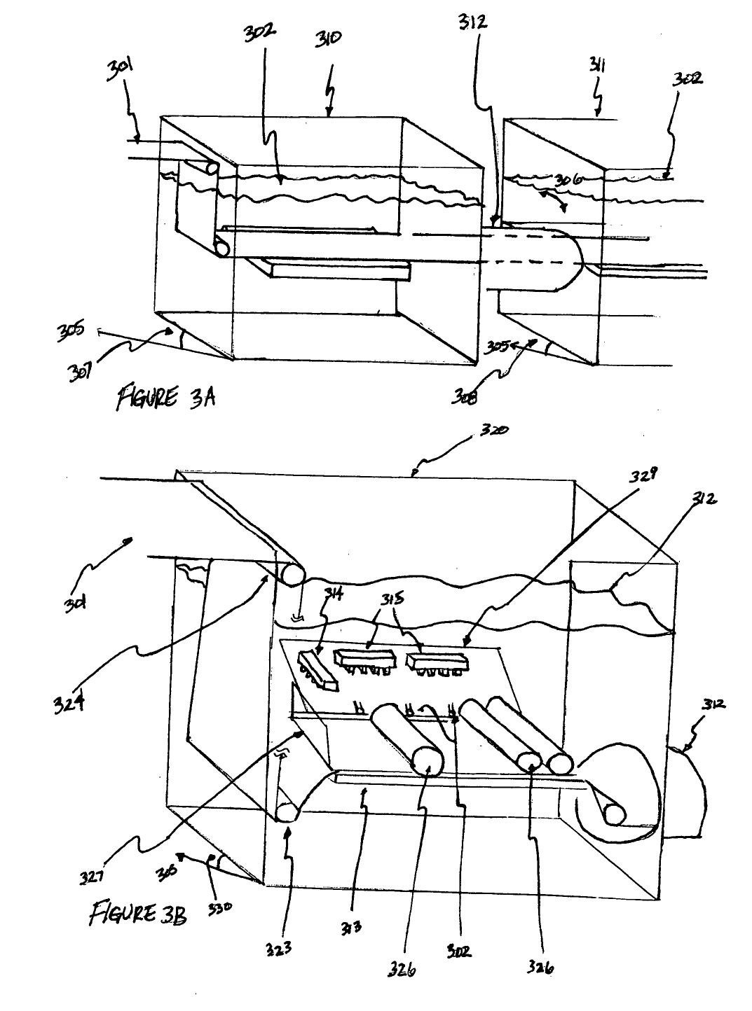

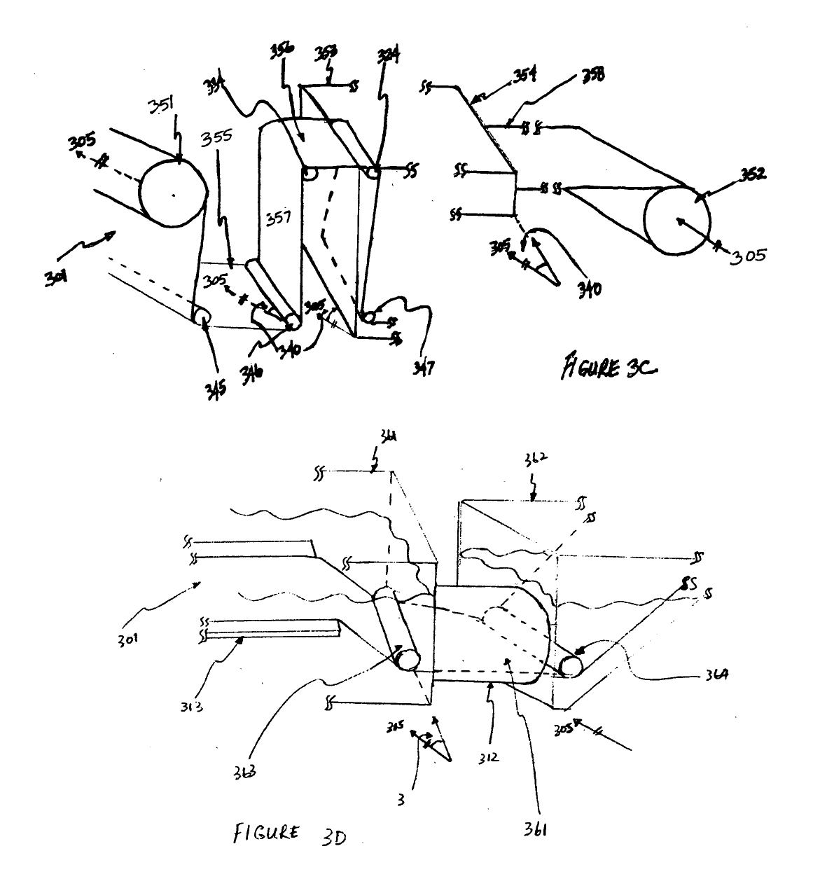

FIG. 3A illustrates two block dispensing and clearing process chambers in series. One block dispensing and clearing process chamber 310 is connected to a second block dispensing and clearing chamber 311 by a cylindrical collar 312. Each container is filled with FSA fluid 302 and the cylindrical collar 312 provides a conduit for both the substrate 301 and the FSA fluid 302 to travel between the process chambers. The cylindrical collar is sealed so the FSA fluid will not leak out, but it also allows the process chambers to rotate independently of each other. The ability to independently rotate each process chamber about the cylindrical collar 312 allows each process chamber to have its individual non-zero angle 307 or 308 with respect to the axis 305, representing the horizontal plane. This provides flexibility to vary the other block dispensing and clearing variables to ensure the most efficient receptor opening filling rate is achieved.

FIG. 3B illustrates a three-dimensional embodiment of a block dispensing and clearing process chamber tilted at a non-zero angle 330, relative to the horizontal axis 305. This example includes only one block and dispensing section and a simplified roller configuration as compared to previous figures. In this embodiment, a substrate 301 enters the process chamber above the level of the FSA fluid 302, wraps around a free roller 324 and submerged below the surface of the FSA fluid. The substrate then wraps around a combination roller 323 that drives and controls tension to the substrate, before resting over the chuck template 313 where the block dispensing and clearing take place. There is an active dispenser 314 that actively pumps blocks over the substrate, two passive dispensers 315 that passively dispenses blocks using gravity, shields 327 and 328 that prevent blocks from dispensing beyond the substrate area, three clearing rollers 326 and multiple cross-flow jet pump nozzles 322 that complement each other to clear blocks from the substrate surface and the receptor site openings. This embodiment illustrates a simple and different concept of a block dispensing and clearing process chamber containing some of the most fundamental components in achieving the desirable results. Not included in this figure are the block recovery and transport manifolds.

FIG. 3C illustrates a transition of a substrate with unfilled receptor openings from a reel to the block dispensing and clearing process chamber, and a transition of a substrate filled with blocks, laminated, and inspected substrate from an inspection module winding onto another reel. Substrate 301 unwinds from a reel 351 with its axis of rotation parallel to the horizontal axis 305. In the embodiment shown, the roller 345 is fixed relative to the reel 351 and is also parallel to the horizontal axis 305. The rollers 346 and 334 are attached to the block dispensing and clearing process chamber 353. When the process chamber 353 is tilted to a non-zero angle 340, the rollers 346 and 334 also rotate by the same amount relative to the rotational axis 305. Consequently, there is a slightly twisted section 355 of the substrate 301 between the roller 345 fixed relative to the reel that is nearest the process chamber and the roller 346 fixed relative to the process chamber that is nearest the reel. Note there can be multiple configurations of the rollers. In a different set up, the roller 345, 340 and 334 can be fixed relative to the reel 351 and thus resulting in a slightly twisted substrate section 356 between roller 334 and roller 324. In all cases however, the twist will occur in a section that would otherwise be parallel to the horizontal plane or axis 305 if there is no tilting of the process chamber. Under no circumstance will the twisting occur in a section of a substrate which is running perpendicular to the horizontal plane or axis 305 such as substrate section 357 because in that case the tension of the substrate cannot be maintained which may lead to uneven movement of the substrate on each longitudinal edge as it travels.

The twisting in a section of the substrate can also occur between a process chamber and the retrieval chamber (as illustrated in FIG. 3D) or between the retrieval chamber and the drying oven (not shown) or in the drying oven (not shown) or between the drying oven and the inspection module (not shown) or between the inspection module and the reel (partially illustrated in FIG. 3C). In the latter case, as illustrated by the second part of the drawing in FIG. 3C, the inspection module 354, along with the rest of the FSA and post-FSA processing modules, is tilted at a non-zero angle 340 relative to the horizontal axis 305. The broken section in the figure represent one series of rollers that are attached to the inspection module and another series of rollers that are attached to the wind up reel 352. There exists between two rollers a substrate section similar to the previously illustrated substrate section 355 which is twisted when the substrate transitions from the inspection module to the wind up reel 352.

FIG. 3D illustrates a substrate section that transitions from a tilted block dispensing and clearing process chamber into a retrieval chamber which is parallel to the horizontal axis 305. The process chamber 361 filled with FSA fluid 302 has the substrate 301 traveling over the chuck template 313 and redirected by a tension roller 363 into the cylindrical collar 312 and redirected by a driving tension roller 364 up an incline inside a retrieval chamber 362 to be removed from the FSA fluid 302. In this embodiment, the substrate section 361 is twisted inside the cylindrical collar 312 between roller 363 and roller 364. Although the collar does not necessarily have to be cylindrical in shape, it must have a cross-sectional area that is wide enough to accommodate the width of the substrate when the substrate travels through flat or at a twisted angle. This illustrates another benefit of having a rotatable collar between the retrieval chamber and a process chamber where the retrieval chamber can be tilted (or not tilted) at a different angle relative to the process chamber. Under this configuration, only the FSA block dispensing and clearing processes taking place within the process chambers need to be tilted and the rest of the pre and post FSA processing can remain parallel to the horizontal plane at a zero tilt angle. Generally, it is simplest to implement the FSA system by having only the process chambers tilted to assist in movement of the blocks on the substrate surface during the dispensing and clearing process while maintaining the retrieval chamber, drying oven, lamination module and inspection module parallel to the horizontal plane, like the wind up reel. However, there may be exceptions where some or all parts of the post FSA processing modules need to be tilted before the substrate reaches the wind up reel, thus a rotatable collar makes an alternative solution possible.

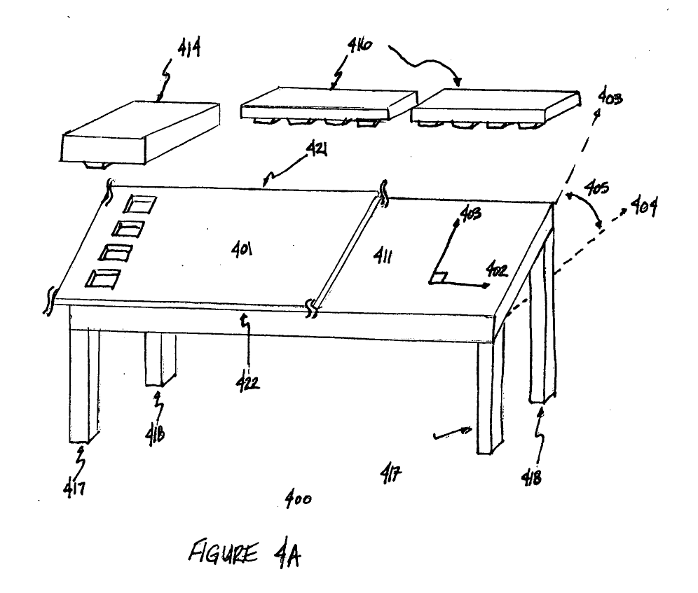

FIG. 4A illustrates a variation from a previously described embodiment where an area is fixed relative to the process chamber and is tilted by rotating the entire process chamber about an axis. FIG. 400 shows an active dispenser 414 and two passive dispensers 416 over an area 411 to receive a substrate 401 which can be tilted. The substrate is a continuous sheet with longitudinal edges 421 and 422 running along the longitudinal axis 402 of the tilted area. In the FSA process, the substrate is continuously moving in the longitudinal direction along axis 402 while the slurry is dispensed over the substrate, with the dispensing and clearing components fixed relative to the area receiving the substrate and the process chamber. The tilted area 411 has a non-zero angle 405 between its transverse axis 403 and a horizontal plane, denoted by axis 404. In this embodiment, the tilt is accomplished by having legs of different lengths to prop up the area. In the present example, the rear legs 418 are longer than the front legs 417 which results in having the longitudinal edge 421 of the substrate higher than the longitudinal edge 422 of the substrate.

The extended length of the legs 418 can be accomplished in different ways. If an existing substrate receiving area 411 has fixed legs of equal length, the rear legs 418 can simply be propped up by a block or an object to increase the overall length of the legs to achieve the desired angle. Otherwise, legs with adjustable length can be used. For example, length extension can be accomplished by having legs made of two sections, one fitting within another, each containing a series of holes along the vertical length of each section. As the outer section slides over and along the length of the inner section, an operator can align the holes and use a pin to lock the two sections together obtaining an extension relative to the shorter legs that corresponds to the desired non-zero angle.

FIG. 4B illustrates a side view of the tilted area 411 with a non-zero angle 405 between the area's transverse axis 403 and a horizontal plane. In this figure, the legs 418 are adjustable as described above, containing two sections, one over another, with overlapping holes between the two sections that can be locked by a pin.

The tilted area aids removal of blocks as the slurry, a mixture of FSA fluid and blocks is deposited near the top longitudinal edge 421 of the substrate and imparts energy in the blocks to slide down toward the bottom longitudinal edge 422 of the substrate with the assistance of the fluid. The tilted surface of the substrate uses gravity to help move the blocks, both in filling openings and in removal of the excess or improperly placed blocks. The non-zero angle is approximately within the range of about 2 degrees to about 45 degrees, often seen between about 5 degrees and about 30 degrees and most preferred between approximately about 8 degrees and about 18 degrees. The non-zero angle cannot be too steep or else the blocks will slide too quickly past the receptors, but if the non-zero angle is too small, it cannot utilize gravity fully to assist in movement of the blocks across the substrate surface. The appropriate angle allows a controlled sliding of blocks such that the blocks are sliding slowly over the substrate surface.

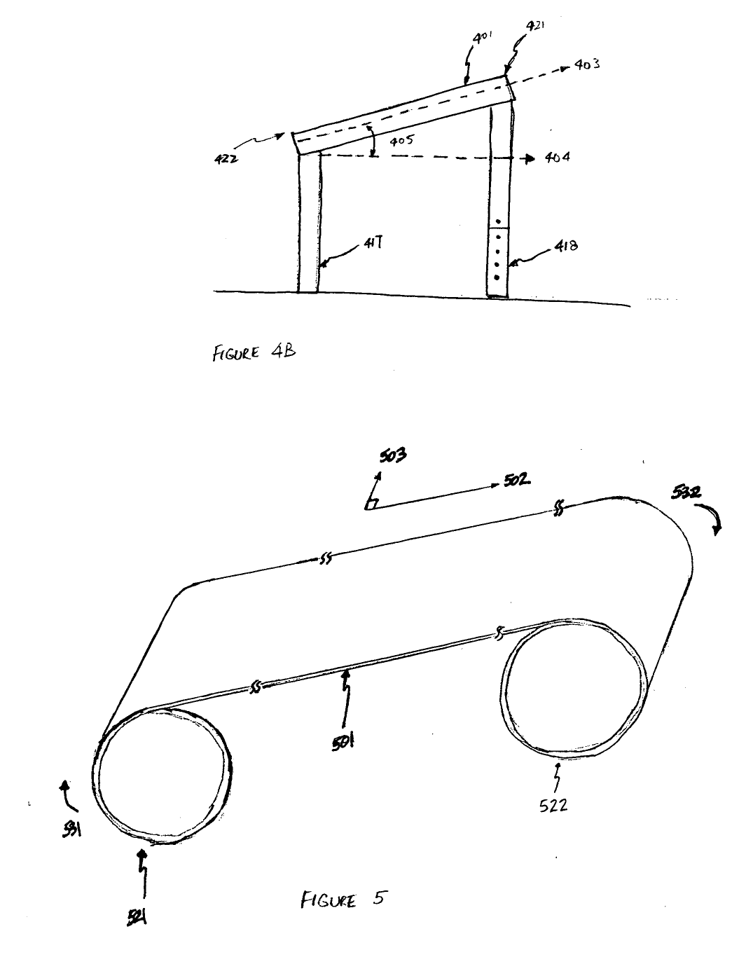

FIG. 5 illustrates a continuous sheet of substrate. Generally, substrates are made of a continuous sheet that may range approximately from about 2 feet to about 2000 feet in length. The length of the sheet depends on the application. For example, performing research and testing new parameters may only require 2 feet to 10 feet but in production, substrates with length from about 200 feet to about 2000 feet are used. Typically substrate 501 comes in a continuous sheet of approximately about 200 feet to about 500 feet long, with its length stretching along its longitudinal axis 502. Because of the significant length, the substrate is normally wound up in a reel and packaged as a roll for easy transport between manufacturing processes. During the FSA process, the substrate unwinds from its reel 521 and travels continuously along its longitudinal axis 502, perpendicular to its transverse axis 503 or the direction of its width. The substrate travels continuously over the substrate receiving area for FSA processing where the slurry is dispensed to fill the receptor openings and subsequently through the post-FSA processes where the substrate is dried, laminated, and inspected before winding up into a different reel 522. The relative height or positions of the reels with respect to each other is not important. The axes of rotation for both reels are generally parallel to the horizontal plane as described in previous embodiments. However, on the occasion where the axis of rotation of any reel is tilted and makes a non-zero angle with respect to the horizontal plane, the objective of the tilt is to not induce unnecessary torsional stress and strain on the substrate which may be a result of the non-zero angle of the substrate extending from the FSA and post-FSA processing modules.

The continuous movement of the substrate along the longitudinal axis during the FSA process and post-FSA process is achieved by various means. The motorized reel located at the end of the post-FSA processing is actively and continuously winding, actively pulling the substrate through the processing modules. Along the processing modules and throughout the FSA and post-FSA processes the driving rollers are used to assist in moving the substrate. The placements of these driving rollers are arbitrary. For example, as described in a previous embodiment of block dispensing and clearing process chamber, there can be two driving rollers in each process chamber, one at each end beyond the chuck template. Similarly, driving rollers can be placed at the two ends of each processing module to assist in driving the substrate through each module if none is placed within the module. Additional driving rollers can further be placed between the unwinding reel and the first process chamber and between the inspection module and the winding reel to assist substrate movement.

Maintaining the appropriate tension of the substrate throughout the FSA process and post-FSA processing is important to ensure proper alignment of the substrate during movement. If the substrate's two longitudinal edges rotate at a speed different from each other, the substrate may slowly misalign. The position of the tension rollers can be adjusted according to the desired tension to ensure that there is no slack in the substrate throughout the system. Furthermore, the driving rollers may also rotate at various speeds adjusting to the changing level of tension at different sections of the substrate. Lastly, slip clutch can also be built into the rollers throughout the system to prevent the substrate from traveling in reverse, thereby ensuring that the substrate only travels in one direction.

In one embodiment, Nanoblocks (NB), one type of blocks applicable in this system, are dispensed onto the substrate by a dispenser system. The aims of the dispenser system are to dispense NBs over the substrate with the desired distribution and without damaging them and without removing NBs from receptor sites. The desired distribution of NBs has as many as possible landing right-side-up and, typically, evenly spread over the substrate. There are many suitable designs of dispenser systems. One embodiment is the cyclonic dispenser driven by ejector pumps fed by FSA solution. The benefit of using ejector pumps is no moving parts contact the slurry, however the ejector pump adds FSA solution to the slurry, decreasing the concentration of NBs within the slurry. The cyclonic dispenser is a good complement to the ejector pump as it allows excess FSA solution to be removed from the slurry. Further, the fluid within, and at the outlet of, the cyclonic dispenser is rotating around the long central axis and this generates centripetal forces on the NBs within the slurry. At the outlet of the cyclonic dispenser, the centripetal force throws the NBs outward to form a broad uniform shower of NBs. The outward motion of the NBs can be confined by adding deflector plates at or beyond the exit of the cyclonic dispenser. Frequently approximately about 60% of NBs land right side up.

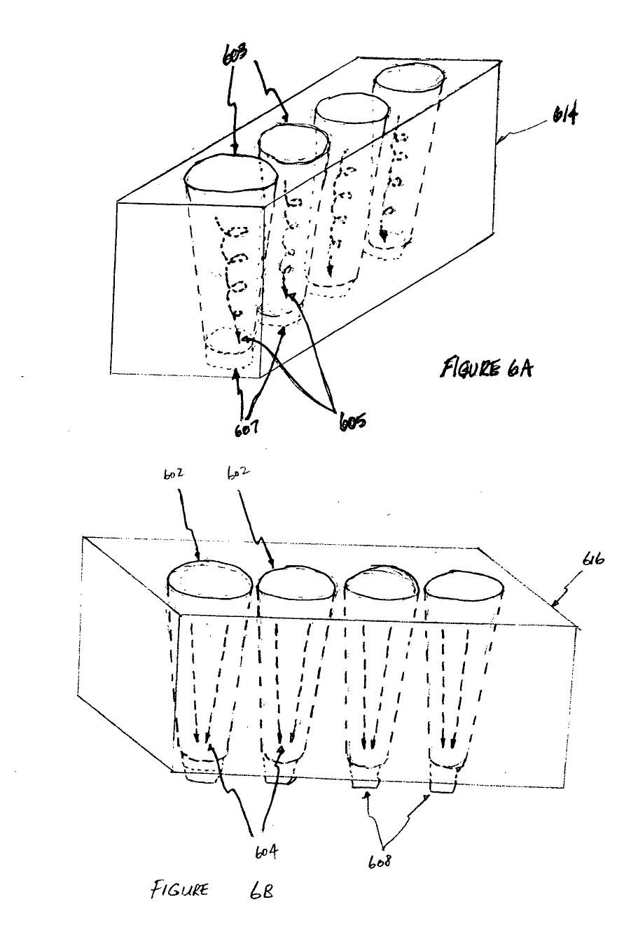

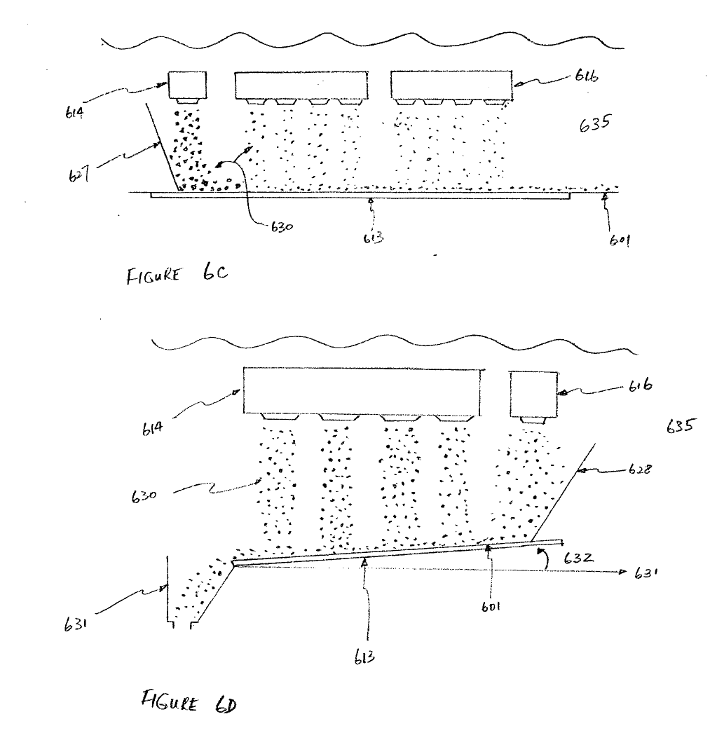

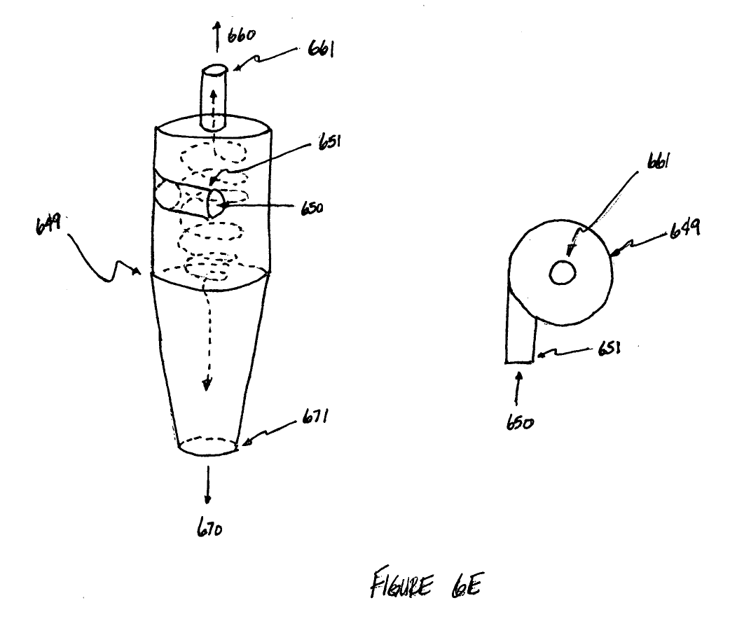

FIGS. 6A and 6B illustrate two embodiments of dispensers that can be used to dispense blocks in the FSA process. FIG. 6B shows a passive dispenser 616 containing four (4) funnel compartments 602 where the blocks are dispensed after they are collected from the blocks cleared from the substrate surface. Often, at least one dedicated ejector jet pump is used to pump excess, recycled blocks from the collector tray into the dispenser funnels. In the passive dispenser 616, the funnels simply functions as a means to direct the blocks in a dispensing process. The blocks are transferred to the top of the funnels 602 where gravity acts on each block for them to fall linearly (604) and randomly onto the substrate surface through the dispenser nozzles 608. An embodiment that actively dispenses blocks is shown in FIG. 6A. FIG. 6A shows an active dispenser 614 containing four (4) funnel compartments 603 where the blocks are pressurized through the nozzles 607 after the blocks are transported from a reservoir and/or re-circulated from a collector tray of excess blocks from the filling process. Generally a dedicated ejector jet pump is used to gather and collect blocks from a block reservoir and a tray collecting excess blocks into the funnels 603. In the case of this active block dispenser, there is another dedicated ejector jet pump that is responsible for generating a cyclonic movement 605 of the blocks inside the funnels so that the blocks are actively pressurized and forced out of the nozzles 607 onto the substrate surface. The cyclonic movement and active forces pressurizing the blocks onto the substrate surface is aimed to force the blocks straight down from the nozzles onto the substrate surface. Part of the reason for employing an active mechanism is because overall there are more blocks gathered into the active dispenser from the block reservoir and the collector of excess blocks as compared to only gathering excess blocks from the collector for the passive dispenser. An active mechanism is appropriate to aid dispensing a larger quantity of blocks. An additional reason for employing this type of active dispensing device is to generate a uniform density of block deposition over a wider cross-section of web than can be readily obtained by passive devices. The number of funnels and nozzles are not limited to the current configuration. There may be more or less funnels and nozzles per dispenser. The appropriate configuration is dependent on the overall size of the process chamber, the size of the dispenser, and the quantity of blocks to be dispensed per dispenser.

FIGS. 6C and 6D show two perspectives of the block dispensing process taking place in the process chamber submerged below the surface of the fluid. The process of block dispensing in both illustrations is entirely within the FSA fluid medium 635. A fluidic medium provides a higher resistance of travel against gravity than air when the blocks exit the dispenser nozzle as compared to a slurry of blocks exiting the nozzle of a dispenser into air. The FSA medium also provides lubricity for the blocks to minimize friction during the dispensing process. A slower and more controlled dispensing in a lubricious environment leads to less damaged blocks as a result of less friction among blocks, and also less impact force on the blocks when it lands on the substrate surface. Additionally, in the case in which the fluid contains water, it can also dissipate charge, thereby reducing or eliminating the chance of circuit damage by electrostatic discharge.

FIG. 6C shows the active dispenser 614 and passive dispenser 616 dispensing blocks from the view of the longitudinal axis of the substrate. In this view, the substrate 601 travels over the chuck template 613 and moves to the right of the page in the same direction as its longest edge. Note that to simplify the illustration, the non-zero angle or tilt of the substrate between its transverse axis and the horizontal plane is not illustrated. There is a shield 627 that may be implemented to guide the falling blocks into the desired area over the substrate surface and to prevent the blocks from falling beyond the edges of the substrate. The shield can be attached to the dispenser or to a frame or to the process chamber, and it is usually close to but not in contact with the substrate surface.

FIG. 6D shows the active dispenser 614 and passive dispenser 616 dispensing blocks from the view of the transverse axis of the substrate. The substrate 601 is resting over the chuck template 613 which is tilted and makes a non-zero angle 632 with respect to a horizontal plane represented by axis 631. In this view, the active dispenser 614 is seen dispensing blocks across the transverse of the substrate while the passive dispenser 616 is dispensing blocks along the longitudinal axis of the substrate. There is a shield 628 for the passive dispenser that is similar to the shield in the previous figure for the active dispenser that is either attached to the dispenser or to a frame or to the process chamber and it is usually close to but not in contact with the substrate surface. The shield 628 also functions to guide blocks and simply prevent blocks from falling beyond the longitudinal edge of the substrate. The excess and improperly positioned blocks are cleared from the substrate surface into a collector tray 631 for re-circulation back into the passive and/or active dispensers.

When viewing both FIGS. 6C and 6D, the active dispenser 614 is generally located perpendicular to the passive dispensers. The active dispenser is parallel to the transverse axis of the substrate while the passive dispenser is parallel to the longitudinal axis of the substrate along the direction of the substrate movement. The passive dispensers are often placed in series with its longest edge in parallel to the direction of the travel, directly above the higher longitudinal edge of the substrate after the substrate is tilted. The active dispenser is often place upstream of both passive dispensers relative to the direction of substrate travel. However, the placements of the active and passive dispensers may be interchanged or rearranged into a different configuration than presented. Therefore the placements of the active and passive dispensers in these drawings are not intended to be limiting to the invention. FIG. 6E, showing both isometric and top views, illustrates the core components of one cyclonic dispense tube 649. These basic components exist in both the active and passive dispensers illustrated in other figures. Dilute slurry 650 enters the cyclonic dispense tube 649 through the input tube 651. Input tube 651 joins the main body of the cyclonic dispense tube 649 at a tangent, which induces the flowing slurry 655 to rapidly rotate around the axis of the cyclonic dispense tube 649. Centrifugal forces keep the NBs away from the central axis of the dispense tube allowing excess FSA fluid 660 to be removed from the slurry. The excess FSA fluid 660 leaves the cyclonic dispense tube 649 through the excess fluid exhaust tube 661. Concentrated slurry 670 is dispensed from the cyclonic dispense tube 649 through exit port 671.

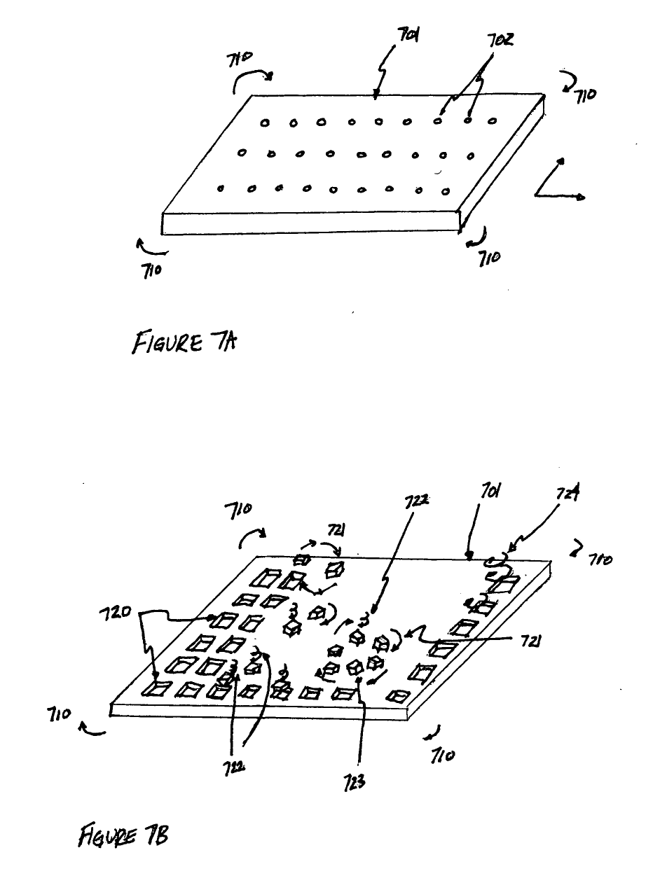

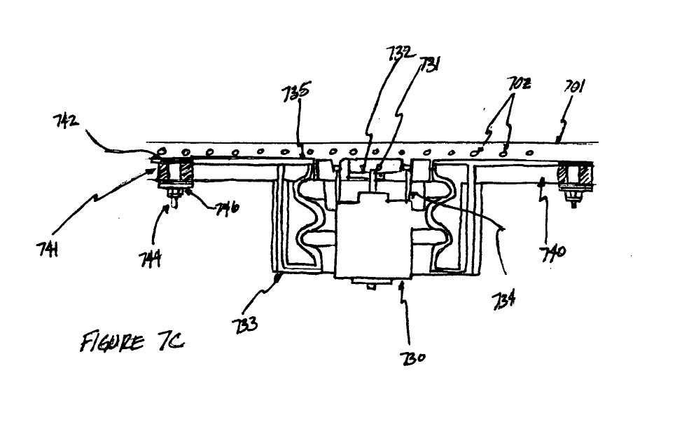

FIG. 7A illustrates a chuck template 701 that is capable of producing circular or any other elliptical vibrations 710. In this figure, there are openings 702 on the chuck template surface that permits the use of vacuum to keep the substrate onto the chuck template surface for good vibration transfer while the chuck template is vibrating. It should be known that vacuum suction is only one mode of transporting a substrate onto the chuck template surface. For instance, as described in previous embodiments, the use of two tension rollers, one on each end of the chuck template, also indirectly functions to keep the substrate onto the chuck template surface when each roller applies a force onto the substrate to maintain tension. The use of a driving roller with gears or sprockets driving a row of track openings along each longitudinal edge of the substrate also indirectly serve to stabilize the substrate to prevent shifting between the chuck template surface and the substrate during vibrations. Although sprockets are helpful in stabilizing the web, they are not necessary; sufficient stability could also be obtained by tension control on rollers and web without sprockets. Further, the use of driven or freely rotating foam rollers pressing against the substrate and chuck template, in a setup similar to that used for the clearing rollers, will provide for good vibration transfer between the chuck template and substrate.

FIG. 7B illustrates the effect of circular or any other elliptical vibrations on the blocks. The purpose of applying vibrations to the chuck template 701 is to keep a slurry of blocks 723 moving over the substrate so the blocks can fill the receptor openings on the substrate. The vibration is intended to counteract the effects of friction and surface forces by adding energy to the system so the blocks can maintain their motion and movement over the substrate surface. The circular motion also serves to generate fluidic forces 721 that act to circulate the device around a receptor site and to rotate 722 the device as it circulates around a receptor site design. The relative magnitude of the effects of vibration can be varied by selecting the appropriate choices of vibration-chuck vibratory pattern and magnitude of motion, substrate/receptor site, block design, and FSA solution additives. Circular or any other elliptical vibrations are selected to generate a net flow of FSA solution immediately around individual receptor sites, forming small vortices 724 along the lip of a receptor site that have a time-averaged net, non-zero, circulation. Consequently, when a block approaches a receptor site, the circulating flow acts to move the block around the region of the receptor site and to rotate the block. The average effect is that a block that passes within close proximity of a receptor site will make multiple passes over the site and present with a different orientation and rotation on each pass. This results in an increased probability of a given block correctly entering and filling the receptor site, and therefore maximizing the overall rate of FSA process receptor filling.

FIG. 7C illustrates the motor mounted to the chuck template used to generate the circular or any other elliptical vibrations on the chuck surface. The source of the vibration power is a direct-current (DC) motor 730 connected to a DC power supply. The invention is not limited to one particular type of motor, but a DC motor is selected for its low cost. The vibration force is generated by an unbalanced rotor that is created by attaching a counter-weight 732 to the motor-shaft 731 with the motor housing 734 anchored to the based of the chuck template 735. The motor-shaft runs perpendicular to the vibration table and the resulting vibration motion is circular in the horizontal plane of the chuck template and the substrate. Vacuum holes 702 are also visible in the top of the table where a low level vacuum is used to keep the substrate close to the surface of the chuck template for maximum vibration transfer, while allowing the substrate to move continuously over the surface of the chuck template. The key parameters to controlling the vibration are excitation voltage, table support bushing size and durometer and rotor size. The excitation voltage controls the amplitude of the frequency of the motor while the unbalance weight, support bushing size and durometer control the softness or damping of the vibrations. An alternate embodiment uses a pneumatic turbine vibrator, such the GT-8 turbine manufactured by Findeva AG of Oerlingen, Switzerland, mounted to the base of the chuck template 735 with the turbine mounted such that its axis of rotation is perpendicular to the top plane of the chuck template 701. The pneumatic turbine uses an unbalanced rotor that is driven by compressed air, and the housing is watertight.

The vibrating chuck template 701 is physically connected to the stationary bottom plate 740 by threaded rods 744, about ¼-28, screwed into tapped holes in the chuck template top and passing through rubber support bushings 741 that are themselves captured within the stationary bottom portion of the chuck template. Motion in the plane of the substrate is permitted, and motion out of this plane limited, by lock nuts 746 on each threaded rod that lightly compress pairs of stacked slip-ring washer 742, approximately about 1″OD×⅜″ID×0.063″ thick PEEK, placed over the threaded rods both above and below the bottom plate of the chuck template. The chuck template 701 is held in place in the FSA process chamber by bolts connecting the bottom plate 740 to the FSA process chamber.

Vacuum holes 702 are also visible in the top of the table where a low level vacuum is used to keep the substrate close to the surface of the chuck template for maximum vibration transfer, while allowing the substrate to move continuously over the surface of the chuck template. The key parameters to controlling the vibration are excitation voltage (or pneumatic pressure), table support bushing 741 size and durometer and rotor size and density. The excitation voltage (or pneumatic pressure) controls the amplitude of the frequency of the motor while the unbalance weight, support bushing 741 size and durometer control the softness or damping of the vibrations. Typical vibration levels used during the FSA process, measured by attaching a light-weight water-proof accelerometer to the top of the chuck template, are in the approximate range of about 150-300 Hz in frequency and about 0.2 to 1.0 g-rms in acceleration, and may exceed these values.

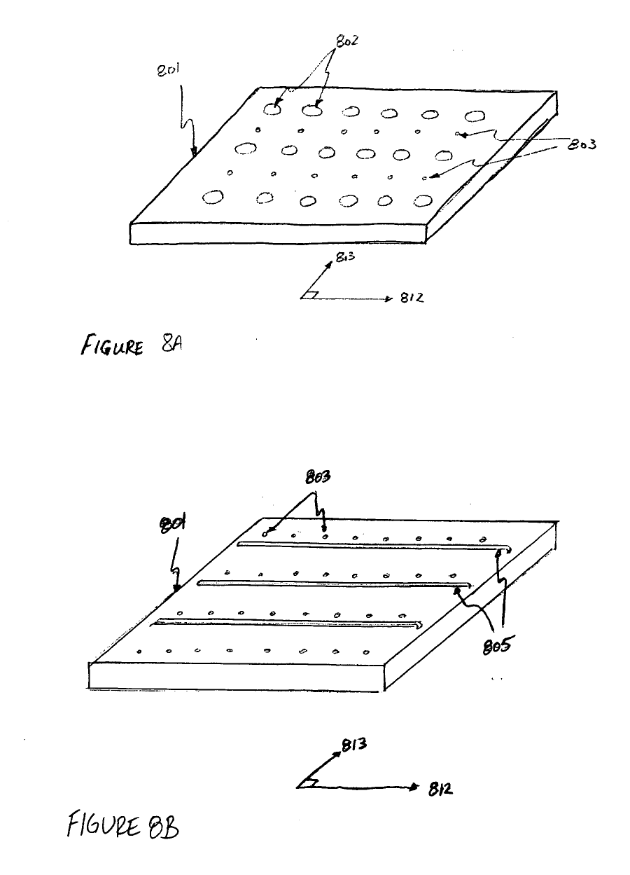

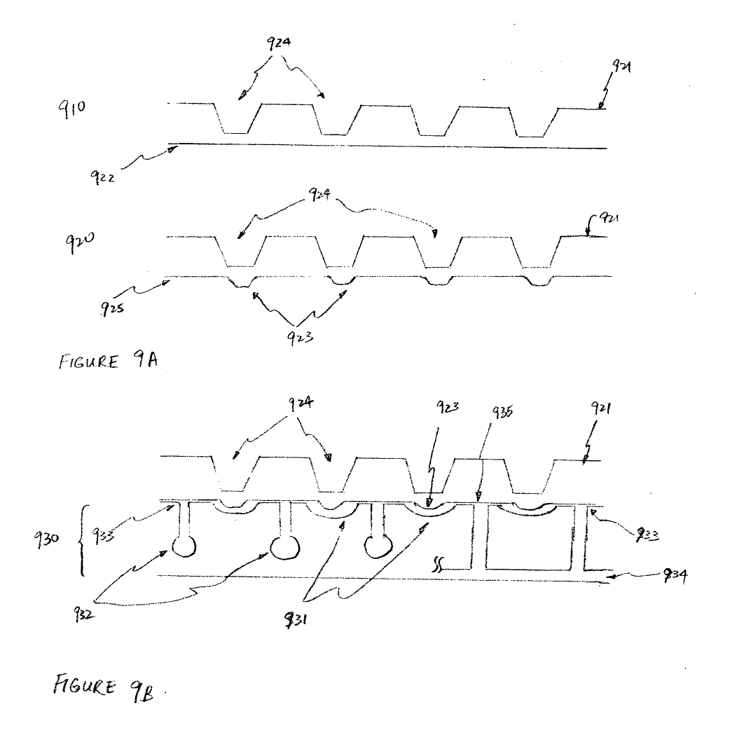

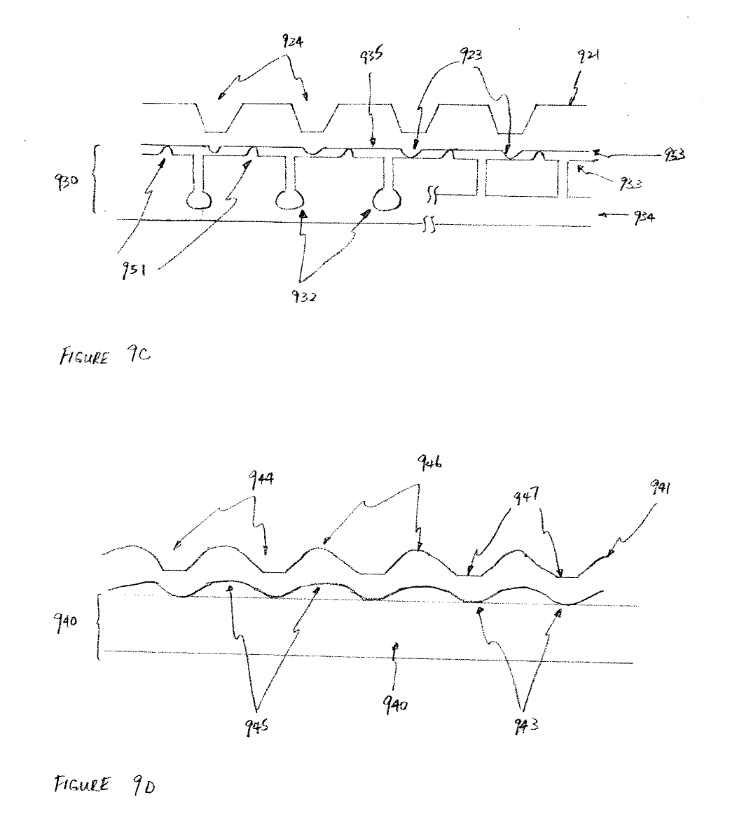

FIGS. 8A and 8B illustrate two configurations of chuck templates that can be used with the current invention. FIG. 8A illustrates a chuck template 801 with parallel rows of dimples 802 lined up along the longitudinal axis 812 of the chuck template. Rows of vacuum openings 803 are also lined up in parallel, along the longitudinal axis 812, and placed between the rows of dimples. In one example, the locations of the dimples 802 are matched to the placement locations of the bottom of the receptor openings in the substrate. FIG. 8B illustrates a chuck template 801 with rib templates 805 lined up in parallel along the longitudinal axis 812 of the substrate. Similar to FIG. 8A, rows of vacuum openings 803 are also lined up in parallel to the rib templates. In this example, the locations of the rib templates 805 are lined up between the bottom of the receptor openings on the substrate while the vacuum openings 803 are located between the bottom of the receptor openings and the rib templates 805. These two configurations are designed for purposes as explained in FIGS. 9A to 9D.

In some cases, the process of forming receptor openings in the substrate may lead to imperfections on the bottom surface of the receptor openings. FIG. 9A has two illustrations for comparison. 910 is a substrate 921 with receptor openings 924 and a smooth bottom surface 922 below the receptor sites, while 920 is a substrate 921 with receptor openings 924 and a bottom surface 925 which has bumps 923 below the receptor openings. Although these bumps 923 formed on the bottom surface underneath the receptor site openings are the only observed imperfections, they may protrude from the bottom surface as much as about 30 μm to about 60 μm, and consequently, affecting the block filling and block removal efficiency.

FIG. 9D illustrates one problem of having bumps on the substrate bottom surface. As the substrate 941 is fixed and positioned onto the chuck template 940, the substrate is pressed downward. When there are bumps 943 on the bottom surface of the substrate as the substrate is pressed, the bottoms of the receptor openings 947 are pushed up by the chuck template surface 940 causing the receptor openings 944 to widen. Consequently, the substrate top surface 946 between the receptor openings is compressed as the openings are forced to open wider. As the opening of the receptor widens and the bottom of the opening is pushed up, blocks are no longer secure in the receptor sites. When vibrations are applied, properly placed blocks can pop out of the receptor opening easily, reducing the efficiency of the filling process. Similarly, because the openings of the receptors are widened, it can also allow inverted blocks or improperly placed blocks to slide in, thus leading to another problem of having blocks with a wrong orientation in the receptors.

The use of dimples and rib templates are two alternatives to mitigate the problem of having bumps on the bottom surface of the substrate. FIG. 9B illustrates a substrate 921 with bumps 923 on the bottom surface secured over a chuck template 930 by vacuum through openings 933. The dimples 931 are aligned with the bumps 923, essentially creating voids on the chuck template surface to fit the bumps. As vacuum is applied through the openings, only the flat portion 935 of the substrate bottom surface is in contact with the chuck template surface so receptor openings 324 will not deform consequent of any bending induced by bumps. The depth of the dimples approximately ranges from about 20 μm to about 100 μm so that the entire bump will be buried in the dimple.

Similarly, FIG. 9C illustrates a substrate 921 with rib templates 951 on top of the chuck template 930 surface. In this embodiment, the rib templates are in contact with the flat portions 935 of the substrate bottom surface 953. As vacuum is applied through the openings between the rib template and the bumps 923, the rib template supports the flat portions 935 of the substrate bottom surface, keeping the substrate close to the chuck template without deforming the receptor openings consequent of the bumps 923. In this embodiment, rather than having a large degree of bending of the substrate which widens the opening of the receptor sites as the substrate is pulled down and positioned, there is only a minimal degree of bending and will not affect the geometry of the receptor site opening. The rib template approximately measures from about 50 μm to about 2.0 mm wide along the surface of the chuck template and measures approximately between about 40 μm to about 300 μm in height. For the taller ribs, the bottom surface of the substrate may experience approximately up to about 200 μm vertical deflection with a sine wave like shape or an equivalent radius of curvature which ranges approximately from about 15 mm to about 30 mm. By aligning the receptor sites on the substrate between the ribs of the chuck, and using tall ribs, the deflection of the substrate results in troughs centered on rows of receptor sites, which can help guide blocks into receptors during FSA processing and hence increase FSA filling rate.

The vacuum channels in these two embodiments may be presented in different configurations. In one configuration, each row of openings is connected by a channel 932 running parallel to the row of openings. All channels terminate in one common space where vacuum is applied to create the suction. Another configuration has an empty space 934 below the surface of the chuck template surface connected to each opening channel. Vacuum is applied to this space to provide the suction necessary for transporting the substrate. The use of dimples and rib templates can be applied to the previous embodiment of a chuck template producing circular or any other elliptical vibrations.

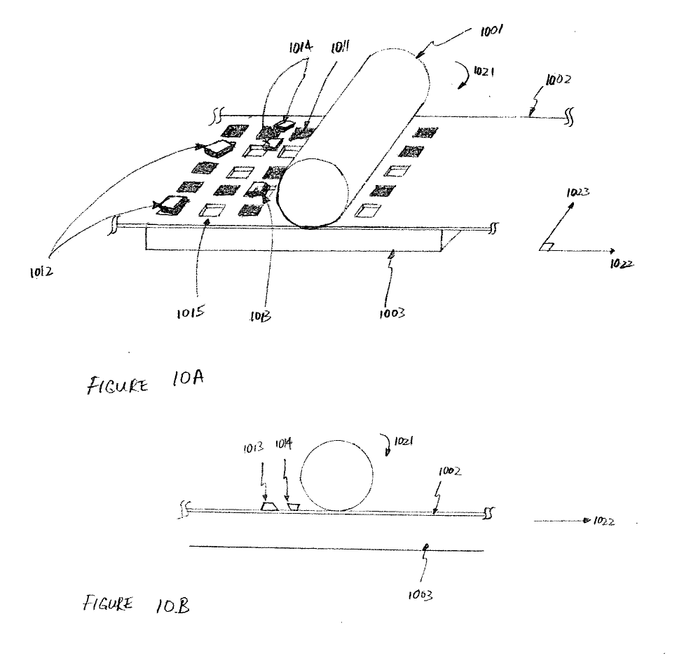

FIGS. 10A and 10B illustrate a three-dimensional and a side view of a clearing roller clearing blocks from the substrate surface, respectively. FIG. 10A is a three-dimensional view of a clearing roller 1001 rotating over a continuous sheet of substrate 1002, received on a chuck template 1003, which is continuously moving along the longitudinal axis 1022 of the chuck template and the substrate. As described in previous embodiments, the number of blocks dispensed onto the substrate surface by the FSA dispenser generally out number the receptor sites on the receptor significantly; the ratio can be as high as about 50:1, depending on process conditions. Dispensed blocks land randomly on the substrate surface and can be found in many different positions during the dispensing process. There are excess blocks 1014 sitting on the surface of the substrate, inverted blocks 1013 protruding out of the receptor site, properly oriented blocks 1011 fitted perfectly into the receptor opening, and right side up but improperly oriented blocks 1012 protruding outside of the receptor site while partially sitting in the receptor opening. In this example, the clearing roller 1001 rotates in a clockwise direction 1021 and moves in an opposite direction relative to the continuously moving substrate at the point of contact. The opposing actions of the clearing roller and the substrate remove excess and improperly positioned blocks from the surface of the substrate and the receptor openings. The rotation motion of the clearing roller acts as a brush against the substrate surface. While the substrate moves along the longitudinal axis, the clearing roller brushes back inverted blocks and improperly placed blocks that are partially protruding from the receptor opening so that no excess blocks or improperly placed blocks will pass forward into the processing stage beyond the clearing roller. The clearing roller functions to remove excess and improperly placed blocks on the substrate surface and that the receptor site openings are either empty or filled with right side up blocks before traveling into a downstream processing section.

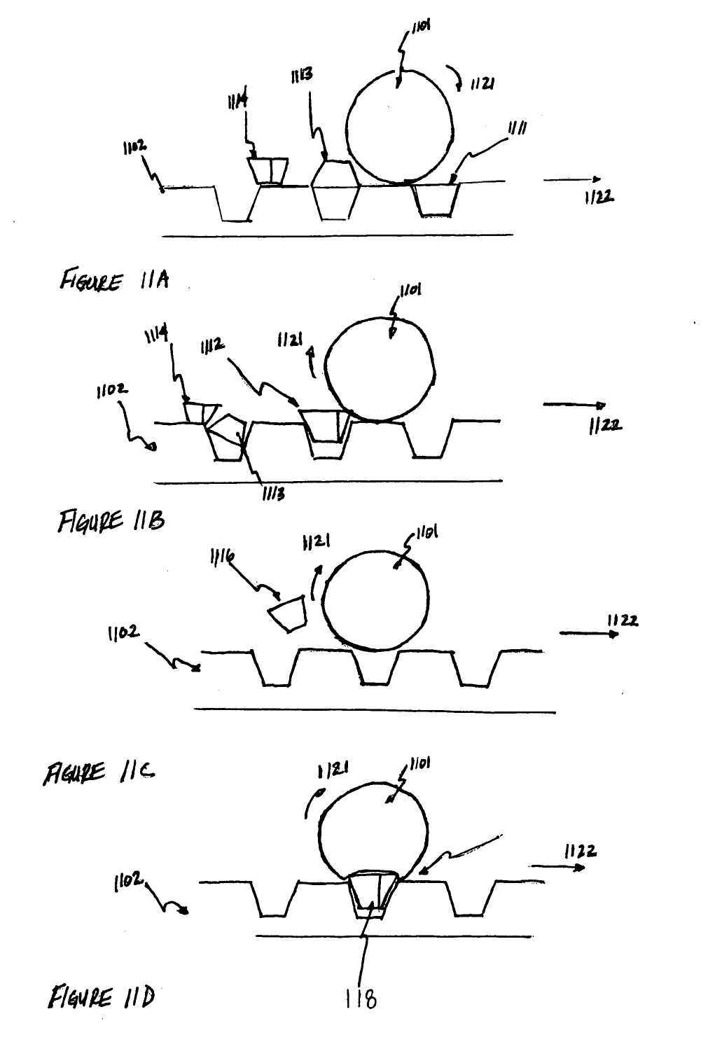

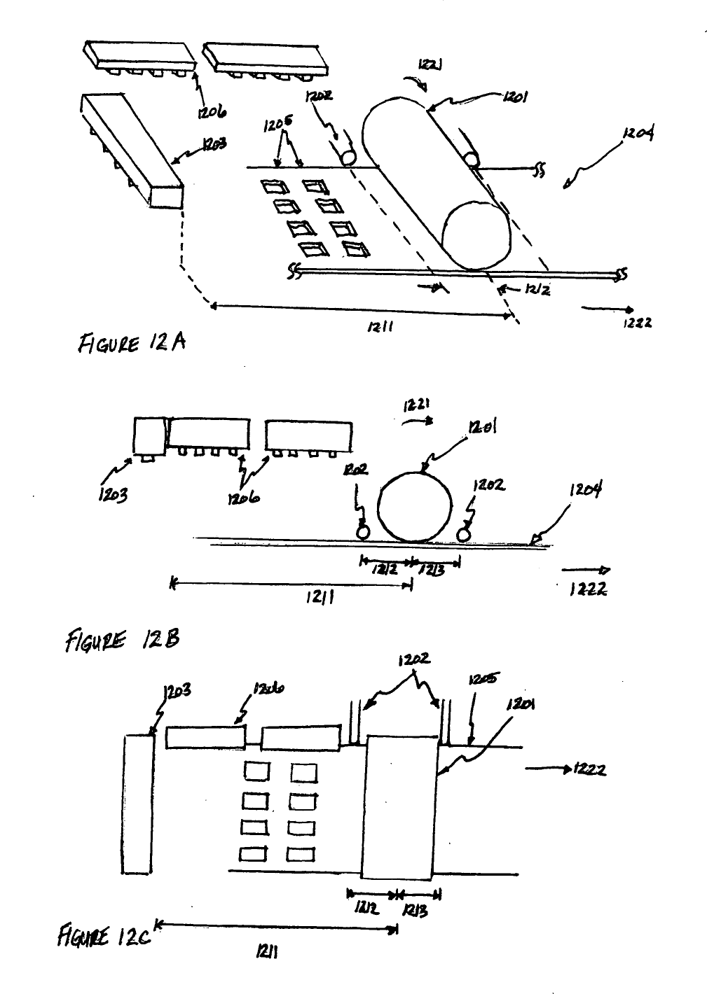

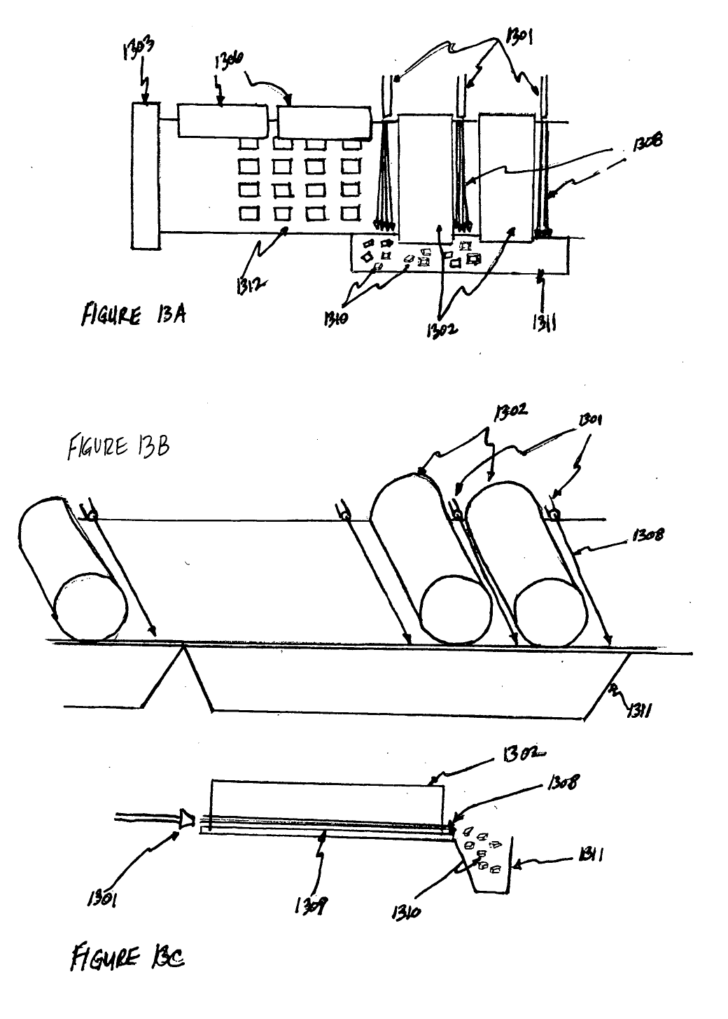

FIGS. 11A through 11D illustrate a side view of the rolling action of the clearing roller in the process of removing blocks on the substrate surface and over the receptor openings. FIG. 11A illustrates an excess block 1114 on the substrate surface and an inverted block 1113 over a receptor site opening approaching a clearing roller 1101 brushing over the substrate surface 1102 in a clockwise rotation 1121. There are no excess blocks after the clearing roller and only a properly seated block 1111 sits in the receptor opening past the roller. Similarly in FIG. 11B, there is an improperly placed block 1112 that is partially protruded from a receptor site opening. As the clearing roller rotates and brushes in the clockwise direction of 1121 while the substrate moves forward along the longitudinal axis of 1122, the excess block 1114, inverted block 1113, and improperly positioned block 1112 are all brushed backwards in a direction opposite to the movement of the substrate. FIG. 11C illustrates a block 1116 that can be any of an excess block, inverted block, or improperly positioned block that is brushed back by the rotation action of the clearing roller. Consequent of the brushing action of the clearing roller, there are generally none to only a few excess blocks on the substrate surface after the point of contact between a clearing roller and the substrate surface. FIG. 11D shows the soft compliance of the clearing roller in not damaging blocks. On the occasion when there are blocks that protrude slightly above the substrate surface because of an improper orientation (1118), or an excess block that is caught underneath the clearing roller, or any block that was not cleared from the substrate surface or receptor opening, the softness of the clearing roller will allow blocks to pass through without being damaged. The blocks will then be removed by either a jet stream of FSA fluid from a cross-flow jet pump nozzle or in a subsequent repeated stage of FSA process. Due to the large number of blocks deposited onto the substrate surface, it is not uncommon that not all blocks are removed by one clearing roller. Usually in each block dispensing and clearing section in a process chamber, multiple clearing rollers are used successively to ensure complete clearing of blocks on the substrate surface.

The clearing rollers used in this application are made of a highly compliant, soft material, such as PVA foam which does not dissolve or breakdown when it is immersed in the FSA fluid. Commercially available smooth PVA clearing rollers with diameters of 40 mm and 60 mm have worked well and other sizes could be used. The unique soft material allows the surface of the rolling pin to catch the excess blocks or the inverted or improper blocks' edges, but not enough to be abrasive or damaging to the surface of the substrate surface. The clearing roller is actively driven by a motor to rotate in a direction opposing the movement of the substrate and rotates approximately at a rate of about 30 rpm to about 60 rpm. The speed will ensure that the roller is effective in removing blocks while not causing any turbulence of the fluid in the tank leading to unsettling of the blocks in the receptor sites. In addition, the roller speed is set at a level to minimize the number of blocks that are brushed backwards from interfering with the roller action from the previous dispensing stage. Furthermore, the clearing roller also exerts a slight pressure onto the substrate surface when it is pressed down onto the substrate surface. The friction generated by the opposing motion against the substrate surface and the slight pressure normal to the substrate surface combines to maintain a level of tension on the substrate when traveling over the chuck template. Besides the use of a rolling pin, other configurations such as the use of a brush or a mechanical wiper functioning with the same principle to remove excess or improperly placed blocks from the substrate surface can be applied.

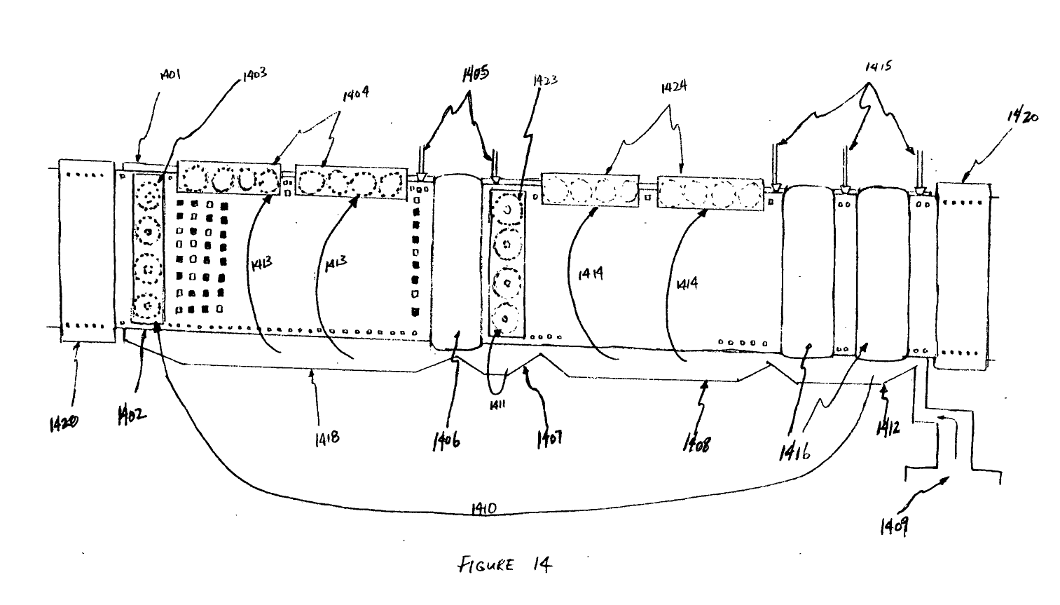

FIGS. 12A to 12C show the use of cross-flow jet pump nozzles in combination with the clearing rollers to clear and remove blocks. FIG. 12A shows a three dimensional view of a block dispensing and clearing section in a process chamber. The block dispensing is performed by one active dispenser 1203 and two passive dispensers 1206 positioned over a substrate 1204 with receptor openings 1205. The block clearing is performed by the cross-flow jet pump nozzles 1202 and a clearing roller 1201, which rotates in a clockwise direction 1221 over the substrate surface while the substrate moves continuously in the direction of the longitudinal axis 1222. The cross-flow jet pump nozzles 1202 are positioned on each side of the clearing roller 1201, along the longitudinal axis, spraying fluid over the surface of the substrate along the transverse axis of the substrate, perpendicular to the direction of travel of the substrate. The jet stream of FSA fluid emitted from the cross-flow jet pump nozzle is aimed parallel and just above the surface of the substrate. The jet stream of fluid serves to remove any excess blocks or improperly placed blocks away from the substrate surface. While the clearing roller brushes back the blocks away in a longitudinal direction on the substrate surface, the jet stream of FSA fluid from the cross-flow jet pump nozzle functions to remove the blocks from the substrate surface in a transverse direction on the substrate surface. Although the cross-flow jet pump nozzle performs a slightly different function compared to the clearing roller, the two clearing components complement each other in their function and in combination provide an effective means of removing blocks from the substrate surface.

FIG. 12B shows a side view and FIG. 12C shows a top view of the embodiment described in FIG. 12A. There is no minimum or maximum number of clearing rollers and cross-flow jet pump nozzles for each block dispensing and clearing section. However, it is practical to have at least two cross-flow jet pump nozzles, one before the clearing roller and one after the clearing roller along the longitudinal axis of the substrate movement. First, having a cross-flow jet pump nozzle before the clearing roller helps to remove as many blocks from the substrate surface using the jet stream of FSA fluid before the clearing roller. A smaller amount of remaining blocks on the substrate surface or improperly placed in the receptor site openings can be more effectively brushed back by the clearing roller and then removed by the first cross-flow jet pump nozzle. Further, as described earlier, there are occasions when excess blocks or improperly positioned blocks could not be cleared by the clearing roller and passes through. Thus the benefit of a second cross-flow jet pump nozzle placed after the clearing roller is to assist in clearing any blocks that were able to pass through the clearing roller. The second nozzle is often positioned along the longitudinal axis, distal to the clearing roller, relative to the direction of the substrate travel. Identical to the first nozzle except for the placement location, the second nozzle pumps fluid along the transverse axis across the substrate surface and aims to clear blocks missed by the clearing roller and the first cross-flow jet pump away from the substrate surface. Two nozzles are shown but more can be used, including additional nozzles either upstream or downstream of the clearing roller. Furthermore, cross-flow jet nozzles can be used in combination with clearing rollers, as discussed, or independently, as isolated excess block clearing jets.

Returning to FIGS. 12B and 12C, in order to complement the brushing action of the clearing roller effectively, the cross-flow jet pump nozzles are generally positioned along the longitudinal axis away from the clearing roller at distances 1212 and 1213. These distances between the nearest cross-flow jet nozzles and the clearing roller are generally within an approximate range of between about 0 mm and about 30 mm, and preferred to be between about 20 mm and about 25 mm. However, depending on the blocks to receptor ratio, the rotational speed of the clearing roller, the flow rate of the jet stream of FSA fluid emitting from the cross-flow jet pump nozzle and the distances 1212 and 1213, may vary from each other and in different sections to achieve the optimal clearing effect.

The cross-section of the cross-flow jet nozzles is typically round, and the nozzle itself is typically fashioned from an approximately about 4 inch length of rigid tubing, with the nozzle-end cutoff perpendicular to the long axis of the tube, and a flexible hose connected to the other end to deliver FSA fluid to the nozzle. Note that other nozzle cross-sections can be beneficially applied, including elongated rectangular and oval cross-sections where the long axis of the nozzle opening is aligned parallel to the surface of the substrate. The dimensions listed below are for nozzles of circular cross-section. Returning to FIGS. 12B and 12C, each cross-flow jet pump nozzle is approximately flush with the longitudinal edge 1205 of the substrate and the bottom of the nozzle ID (inside diameter) is placed above the substrate surface approximately within a range of about 1 mm below and about 5 mm above, generally between about 0 mm and about 5 mm and preferred to be between about 0 mm and about 1 mm. The placement and orientation of the cross-flow jet pump nozzle affects the spraying direction of FSA fluid and thus directly affect the clearing efficiency. The speed of FSA solution exiting the cross flow jet nozzle is determined by the volume flow rate of FSA solution through the nozzle and the nozzle ID. Exit speeds in the approximate range of about 0.5 m/sec to about 1.5 m/sec are effective and speeds in the range of 0.6 m/sec and 0.9 m/sec are preferred. Too low speed is not efficient at clearing blocks whereas too high speed will remove properly seated blocks from receptor sites. Cross flow jet nozzle inside diameters (ID) in the approximate range of about 0.5 mm to about 10 mm are used with 6 mm a common ID. For 6 mm ID, the volume flow rate of FSA solution pumped through the cross-flow jet nozzle is commonly in the range of 1.0 L/min to 2.0 L/min and preferably in the range of 1.3 L/min to 1.7 L/min. For other nozzle cross-sections, the volume flow rate of FSA fluid through the nozzle is adjusted to achieve the desired fluid speed at the nozzle exit, with effective and preferred exit speeds as given above.

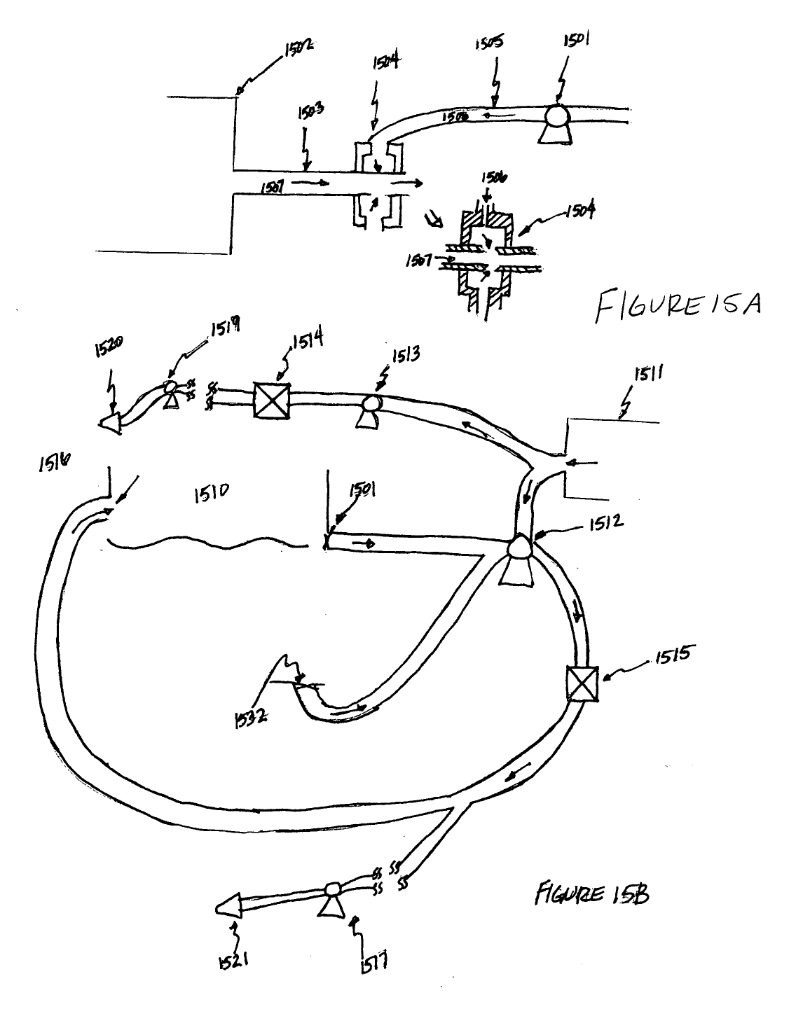

FIGS. 13A to 13C illustrate the importance of having the cross-flow jet pump nozzle spraying the FSA fluid in the proper direction to ensure optimal block clearing efficiency. FIG. 13A shows the top view of the cross-flow jet pump spraying FSA fluid; FIG. 13B shows a three-dimensional view of the block clearing components; and FIG. 13C shows a transverse side view of the block clearing components. Depending on the total number of dispensing and clearing sections and the size of the process chamber, all sections together can potentially be entirely immersed in a tank containing up to over 1000 L of fluid. Corresponding to the overall size of the tank and the amount of fluid contained within the tank, the rate of fluid flowing out of the cross-flow jet pump nozzle is relatively small.

The flow rate of the FSA fluid exiting the cross-flow jet pump nozzle can approximately range from about 100 mL/min to 5 L/min, generally found to between approximately about 500 mL/min and about 4 L/min and most preferred to be between approximately about 750 mL and about 3 L/min. For example in FIG. 13A, the flow rate is selected to ensure that there is sufficient kinetic energy in the jet stream of FSA fluid 1308 to push the blocks 1310 from the substrate surface 1312 into the collector tray 1311 in the opposite edge relative to the cross-flow jet pump nozzle. The cross-flow jet pump nozzle is oriented in a direction where the jet stream travels directly perpendicular to the longitudinal axis of the traveling substrate such that the FSA fluid only need to clear blocks in the shortest path between the nozzle and the collector tray. Furthermore, if any of the cross-flow jet pump nozzles is oriented differently, the FSA fluid may be sprayed into the clearing roller 1302 or in a direction oriented towards the longitudinal axis where it does not have sufficient energy to remove blocks from the substrate surface. Given the relatively small flow rate of the FSA fluid emitting from the cross-flow jet pump nozzle relative to the overall volume of the FSA fluid in the tank, generating turbulence for the overall system is unlikely. However, the flow rate is managed to balance the optimal clearing efficiency while minimizing local turbulence that may affect the blocks that are oriented properly and deposited into receptor site openings.

FIG. 13C shows a jet stream of FSA fluid 1308 is barely skimming the substrate surface 1312 and has sufficient energy to push blocks 1310 into the collector tray 1311. A diffuser screen backstop may be included on collector tray 1311 to help catch blocks as they are blown off the substrate. The diffuser screen allows the fluid jet from the cross-flow jet nozzle to pass through while directing the blocks down toward the bottom of the collector tray. Note that the jet stream is parallel to the substrate surface along the entire surface of the substrate. The purpose of a parallel jet stream is to prevent the jet stream from hitting the substrate at an angle that may inadvertently dislodge some properly placed blocks situated in the receptor openings. Therefore, the cross-flow jet pump nozzle must maintain at least a certain minimum flow rate for the FSA fluid to have enough energy to travel across the substrate surface. Note also that the substrate surface in these descriptions have been parallel to the horizontal plane with a zero tilt angle. In practice, the substrate is likely to be tilted and so the cross-flow jet pump nozzle will need to be tilted to maintain a jet stream trajectory parallel to the surface of the substrate surface.

The block dispensing components and the clearing components are tied together by the circulation system that re-circulates the blocks and the FSA fluid into the dispensers and the cross-flow jet pump nozzles. FIG. 14 shows a top view of a FSA block dispensing and clearing process chamber with the basic block dispensing and clearing components. FIG. 14 also shows the paths in which blocks are recycled into the various block dispensers. As the substrate 1402 is driven along and over the chuck template 1401 by the driving rollers 1420, blocks are continuously deposited on to the substrate surface from the active dispensers 1403, 1423 and the passive dispensers 1404, 1424. As the blocks are removed from the substrate surface by the clearing rollers 1406, 1416 and the cross-flow jet pumps 1405, 1415, the blocks are collected by the collector trays 1407, 1408, 1412 and 1418. Collector tray 1407 mainly collects the overflow of blocks dispensed from the active dispensers 1423 and blocks cleared by the clearing roller 1406 and cross-flow jet pump 1405, while collector trays 1408 and 1418 collect mainly overflowing blocks that are dispensed from the active dispensers 1403, 1423 and the passive dispensers 1404 and 1424 respectively. Furthermore, collector tray 1418 also collects blocks that are removed by the first clearing roller 1406 and the first set of cross-flow jet pumps 1405. Collector tray 1412 collects mostly blocks that are cleared by the clearing rollers 1416and cross-flow jet pumps 1415 while it is also connected to a block reservoir 1409 containing unused blocks.

Blocks collected in the collector trays are re-cycled back into the active and passive dispensers. As an example in the current embodiment, the cleared blocks from the collector tray 1418 are recycled, as indicating by arrows 1413, into the passive dispensers 1404 with the assistance of an ejector jet pump (not shown). Similarly, cleared blocks in the collector tray 1408 are recycled, as indicated by arrows 1414, into the passive dispensers 1424 also with the assistance of an ejector jet pump on tube 1411. The cleared blocks in collector tray 1407 are recycled back into the active dispenser 1423 via an ejector jet pump, while the cleared blocks in 1412 are mixed with unused blocks from the reservoir 1409 and cycled into the active dispenser 1403. Unused blocks from reservoir 1409 are added to make-up for blocks that leave the process tank and to initially charge the system with blocks. Note that the configurations of the collector tray to collect blocks are not limited to the description or as shown in the drawings, more or less collector trays can be used, and the cleared blocks do not have to be exactly recycled into the trays as described above. Different circulation configurations that may be more suitable to the set up and different placements of the dispensing and clearing components may be used.

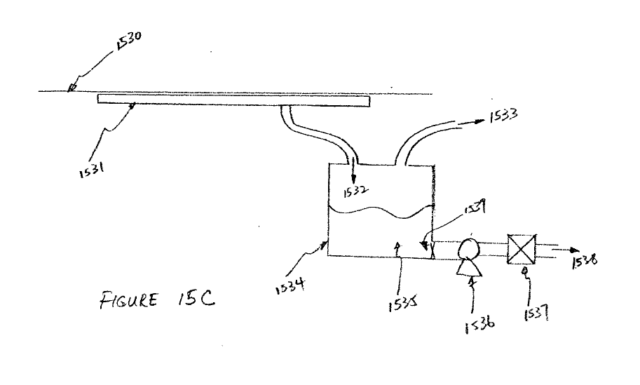

Similar to the blocks, the jet stream of FSA fluid or solution from the cross-flow jet pump nozzles is both recycled from solution within the process chamber as well as from a reservoir of fresh FSA solution. FIG. 15A shows the means of using an ejector jet pump 1504 to recycle blocks and FSA solution in the process chamber. Often, the slurry of blocks and the FSA solution used for the cross-flow jet pump fluid are recycled in separate and different circulatory paths. In FIG. 15A, a mechanical pump 1501 is used to push the solution in a tube or pipe 1505. As the solution from tube or pipe 1505 is joined with another tube or pipe 1503 at ejector jet pump 1504, the solution flow 1506 created by the mechanical pump 1501 will draw solution from the tube or pipe 1503 to create a flow 1507 in pulling or driving solution from a container or reservoir 1502. The mechanical pump only needs to be a pump that gives high solution flow rate. It can be, but not limited to, any of centrifugal pump, positive displacement pump, or gravity feed pump. Only clean, block-free FSA solution 1506 is pumped through the mechanical pump, whereas the FSA solution and block slurry 1507 can be pumped by the ejector jet pump. The ejector jet pump 1504 has no moving parts, and hence can pump slurry without damaging the blocks. Flow from one mechanical pump can be split to drive several ejector jet pumps. There is often at least one dedicated ejector jet pump used for each dispenser and each cross-flow jet pump nozzle. The flow rate at which the blocks and the FSA fluid are circulated for each dispenser and each cross-flow jet pump may vary and thus at least one dedicated ejector jet pump for each dispenser or each cross-flow jet pump is most practical and simple to control the flow rate.

FIG. 15B shows a circulatory system that utilizes mechanical pumps to recycle and replenish fluid in a process chamber and a cross-flow jet pump nozzle, using fluid from a reservoir and fluid from the container. A fluid filled process chamber 1510 has both an overflow valve 1531 and a drainage valve 1532 for excess FSA fluid to escape. A mechanical pump 1512 is used to recycle FSA fluid into the process chamber as well as to replenish fluid into the cross-flow jet pump. Specifically, this mechanical pump 1512 drives fluid from both a FSA fluid reservoir 1511 and the respective overflow valve 1531 and drainage valve 1532 through a filter 1515 back into the process chamber 1516. The same mechanical pump 1512 also drives FSA fluid into another path, through another dedicated mechanical pump 1517 into a cross-flow jet pump nozzle 1521. The function of a dedicated mechanical pump 1517 for the cross-flow jet pump nozzle 1521 is to ensure that there is a sufficiently high fluid flow exiting the cross-flow jet pump nozzle. Similarly, FSA fluid from the reservoir can be used directly to replenish the FSA fluid loss in a cross-flow jet pump nozzle. For instance, as illustrated, an mechanical pump 1513 can be used to directly draw fluid from the reservoir 1511, through a filter 1514, and through a dedicated mechanical pump 1519 into a cross-flow jet pump nozzle 1520. The purpose of the filters 1515 and 1514 are to filter any blocks that may have escaped the system or any extraneous or unwanted particles from clogging the system or creating friction among the blocks during the block dispensing process thereby damaging the blocks. Note that the FSA fluid circulation system in a process chamber is not limited to the configuration as described, but can be configured in different ways as considered most efficient and appropriate for the particular FSA process design.

If the substrate and all dispensing and clearing components are entirely submerged under FSA fluid, the use of vacuum suction to position the substrate onto a vibrating chuck template will inadvertently remove FSA fluid from the processing as well. The circulation system as shown in FIG. 15C illustrates the recycling of FSA fluid collected from vacuum suction generated in the chuck template to position a substrate onto the chuck template. As the substrate 1530 moves along and over the chuck template 1531, a vacuum 1533 is constantly applied to the substrate through a container 1534. The vacuum 1533 is generated by a mechanical vacuum pump (not shown). Since the substrate is immersed in FSA fluid, fluid 1532 is removed from between the substrate 1530 and the chuck template 1531 through the vacuum openings on the chuck template and collected together 1535 in the container 1534. A drainage valve 1539 is located at the bottom of the container and connected to positive displacement mechanical pump 1536 and a filter 1537 which drives the fluid back into the process chamber. This circulation serves the purpose not only to conserve the FSA fluid and recycle it back into the process chamber, but it also helps to prevent damaging the electrical components that creates the vacuum.

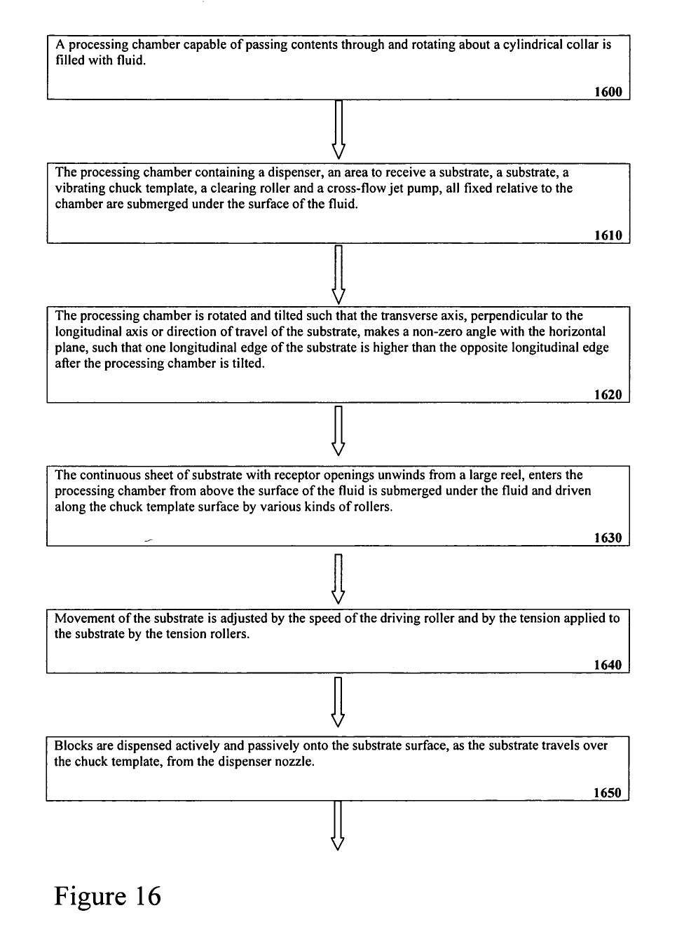

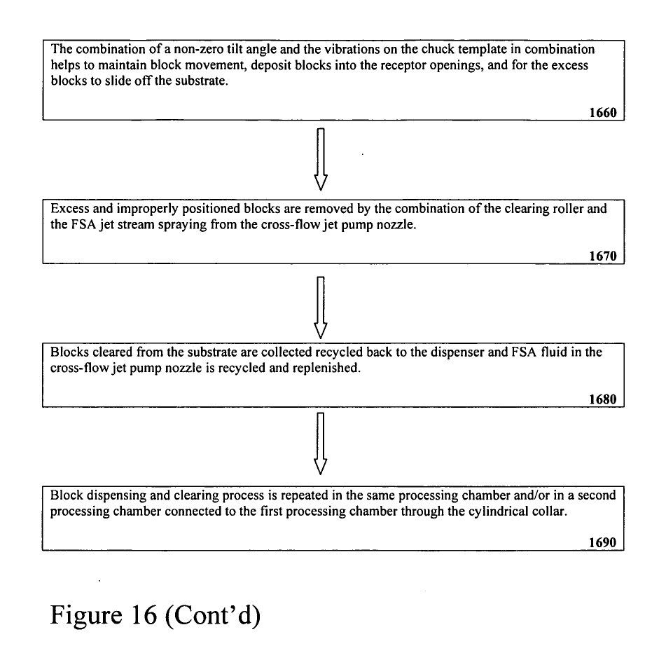

FIG. 16 illustrates a block diagram of an exemplary method in which the blocks are dispensed and cleared within a block dispensing and clearing process chamber in accordance with one embodiment of the invention. At block 1600, the process chamber is sufficiently filled with FSA fluid to cover the primary process components such as the chuck, the web, the dispense nozzles, and the clearing roller. The fluid provides a lubricious environment for the block dispensing and clearing to take place, providing a more controlled process and minimizing damage to the blocks during dispensing and clearing. At block 1610, all the components used for block dispensing and clearing in the process chamber are submerged under the surface of the fluid. In essence, all processes related to block dispensing and block clearing will take place under the surface of the fluid. At block 1620, the entire process chamber is tilted and rotated about the longitudinal axis or the axis of travel of the substrate. Rotation of the chamber will cause the substrate to tilt and have one longitudinal edge higher than another so that the blocks are imparted gravitational potential energy to slide along the transverse axis of the substrate from the higher longitudinal edge to the lower edge. The continuous sheet of substrate with receptor openings originates from a large reel outside the process chamber, enters the chamber above the surface of the fluid and is submerged below the surface of the fluid and driven over the chuck template surface by various driving rollers, tension rollers and free rollers. The block dispensing components and the clearing components are fixed relative to the chamber so that the only continuously moving components in the process are the substrate and rollers that are driving the substrate, and the clearing rollers. The speed of the substrate is controlled by the driving rollers and modulated by the tension rollers that control the tension on the substrate. At block 1650, blocks are both actively and passively deposited onto the substrate from the dispenser nozzle. Generally, the active dispensers dispense more blocks per minute than the passive dispensers and the location of the active dispensers and the passive dispensers may vary. At block 1660, the tilted non-zero angle of the substrate and the vibrations on the chuck template in combination helps to maintain block movement on the tilted substrate surface and assist in depositing blocks into the receptor site openings. Excess blocks with sufficient energy on the surface of the substrate passively slide off the surface without any external assistance. At block 1670, the excess and improperly positioned blocks are actively removed by the combination of the clearing roller and the FSA jet stream emitted from the cross-flow jet pump nozzle. Often there are so many blocks on the substrate surface that only a small portion of the blocks passively slides off the surface without external assistance. At block 1680, the blocks that are cleared from the surface of the substrate are collected and recycled back into the dispensers. Similarly, FSA fluid from the cross-flow jet pump nozzle is also recycled by using the fluid inside the process chamber. An excess reservoir of blocks and an excess reservoir of FSA fluid will often be drawn from replenish the loss of blocks and FSA fluid throughout the process. At block 1690, the block dispensing and clearing process is often repeated as a second section in the same process chamber and again in a different process chamber. Due to the random nature of the FSA process, repeated block dispensing and clearing are performed to maximize the filling efficiency of the FSA process.

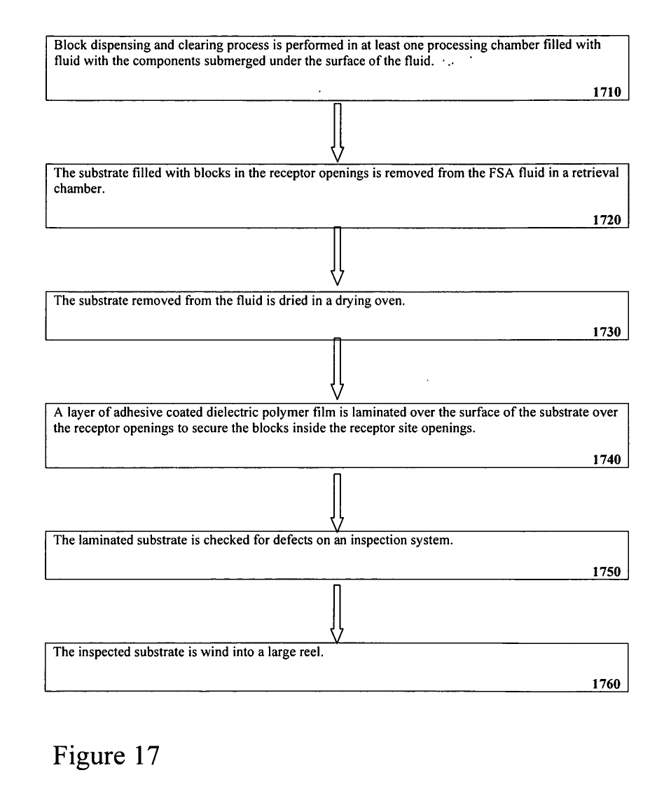

FIG. 17 illustrates a block diagram of an exemplary method in which the FSA blocks deposited onto the substrate is post-processed. At block 1710, the FSA block dispensing and clearing process takes place in a fluid-containing process chamber as described in FIG. 16. This is the block dispensing and clearing process only and is often repeated in more than one process chamber, as described in FIG. 16. At block 1720, the substrate leaves the final process chamber and is removed from the fluid inside a retrieval chamber. The retrieval chamber is connected to the process chamber but is a container with an incline. Using rollers to drive and change direction of the substrate, the substrate moves up the incline and out of the fluid. At block 1730, the substrate is transferred into a drying oven where all the FSA fluid is evaporated and the substrate containing blocks are dried for further processing. This drying step is helpful, but not necessary; the subsequent lamination step can also be done on a wet, or undried, substrate. At block 1740, the dried substrate containing blocks within the receptor openings are laminated with a layer of adhesive coated dielectric polymer film, such as polyimide, polyethylene terephthalate, polyethylene naphthalate, or polyether imide. The adhesive bonds the laminate to the substrate and blocks. At block 1750, the laminated substrate is inspected by an inspection module to ensure that the receptor openings are each properly filled with a right-side-up and a correctly oriented block. At block 1760, the inspected substrate is wound onto a large reel. The reel allows the substrate to be easily transferred and processed in subsequent manufacturing steps.

Certain embodiments are described below in the context of claim language including the following claims:

An apparatus for depositing blocks into receptor openings comprising a dispenser positioned above an area to receive a substrate, the substrate being tilted in a container containing a fluid, wherein the area to receive a substrate forms a non-zero angle between a transverse axis, perpendicular to a longitudinal axis and direction of travel of the substrate, and a horizontal plane, whereby one longitudinal edge of the substrate is higher than another longitudinal edge. In one configuration of the apparatus, the dispenser dispenses a slurry of blocks comprising blocks and a lubricious fluid. In this configuration, the fluid may be filled to a level ranging from a point between a highest point of the tilted substrate to a point above the dispenser nozzle. Still in this configuration, wherein the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. The substrate in the apparatus can be a continuous sheet, at least 2 feet in length along the longitudinal axis, unrolls from one reel and rolls up into another reel and is advanced continuously along the longitudinal axis. In one configuration, the non-zero angle of the apparatus can be between an approximate range of about 5 degrees and about 25 degrees. In this same apparatus configuration, the area to receive a substrate that is tilted have legs with adjustable height, where legs below one longitudinal edge are raised or extended to be longer than legs below another longitudinal edge. Similarly, in this apparatus configuration, the area to receive the substrate that is tilted is fixed relative to the container and naturally rests in a position parallel to a horizontal plane but reaches a non-zero angle between the transverse axis and the horizontal plane by rotating the container about the longitudinal axis.

An apparatus for depositing blocks into receptor openings of a substrate comprising: a container containing fluid; a dispenser positioning above an area to receive the substrate; and a chuck template having at least one of openings for vacuum suction and capability of generating circular or any other elliptical vibrations. In one configuration, the dispenser of this apparatus dispenses a slurry of blocks comprising blocks and a lubricious fluid. Furthermore, the fluid may be filled to a level ranging from a point just above the substrate to a point above the dispenser submerging at least one of the substrate, the chuck template and the dispenser. Still in this configuration, the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. In another configuration of the apparatus, the substrate is a continuous sheet with receptor openings on one surface, at least 2 feet in length along its longitudinal axis, unrolls from one reel and rolls up into another reel and is advanced continuously along the longitudinal axis of the substrate and the area. Further in this configuration, the receptor openings in the substrate are formed from at least one of processes including embossing and hot-stamping. In another configuration, the circular or any other elliptical vibrations oscillate within an approximate frequency range from about 150 Hz to about 350 Hz and within an approximate range of vibration acceleration of about 0.13 g-rms to about 1.5 g-rms with sinusoidal waveforms. Also, the substrate is positioned onto the chuck template by vacuum through openings on the chuck template, or by any other means to fix the substrate that can also be removed easily. Further still, the circular or any other elliptical vibrations are generated by at least one of a pneumatic vibrator, a pneumatic turbine vibrator, and a motor with a counterweight. Still in this configuration, the circular or any other elliptical vibrations are controlled by at least one of excitation voltage, support bushing size and durometer, rotor size, air flow rate, and air pressure. In another embodiment of the apparatus, the substrate is positioned onto the chuck template by two rollers whose axis of rotation is parallel to a transverse axis of the substrate, each located perpendicular to and along the longitudinal axis of the substrate, just beyond the chuck template, pressing down onto the substrate over the chuck template. In yet another configuration, the chuck template has at least one of dimples and rib template on its surface. Furthermore, the substrate receptor sites sit directly over the dimples and the openings for vacuum suction are located between receptor site openings. Alternately, the rib templates on the chuck template are aligned in parallel along a longitudinal axis in a direction of substrate movement at positions of gaps between placements of the receptor openings on the chuck template and the openings for vacuum suction on the chuck template are located between the receptor opening placements and the rib templates. In this alternate form, each of the rib template may rise from about 50 μm to about 2.0 mm above surface of the chuck template and the substrate may experience up to approximately 200 μm vertical deflection with a sine wave like shape or equivalent radius of curvature ranging approximately between about 15 mm and about 30 mm.

A section of an apparatus for depositing blocks into receptor openings comprising: a container containing fluid; a dispenser positioned above an area to receive a substrate; and at least one of a clearing roller that rotates over surface of the substrate and a cross-flow jet pump to remove and clear improperly positioned blocks from the surface of the substrate and the receptor openings. In one embodiment, the dispenser dispenses a slurry of blocks comprising blocks and a lubricious fluid. Furthermore, the fluid may be filled to a level ranging from a point above the substrate to a point above the dispenser, submerging at least one of the substrate, the cross-flow jet pump, the clearing roller and the dispenser below surface of the fluid. Additionally, the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. In another embodiment of the apparatus, the substrate is a continuous sheet with receptor openings on one surface, at least 2 feet in length along its longitudinal axis, unrolls from one reel in one end and rolls up into another reel and is advanced continuously along the longitudinal axis of the substrate. In yet another embodiment, the clearing roller actively rotates at a rate of approximately 40 rpm brushing against the surface of the substrate in an opposite direction against movement of the substrate. Further in this embodiment, the clearing roller presses onto the substrate and creates a tension in the substrate consequent of frictional forces created by opposing movement between the clearing roller and the substrate at contact. Also, the clearing roller is made of a soft material, such as PVA foam. Still in this embodiment, the clearing roller has an approximate diameter of about 35 mm to about 65 mm, an approximate length longer than the width of the wider of the chuck template and substrate, in line with the longitudinal axis of the clearing roller that is parallel to a transverse axis of the substrate and perpendicular to movement direction of the substrate. Still in this embodiment, the clearing roller is positioned away from the dispenser, along the longitudinal axis of the substrate, in direction of the moving substrate. In a different configuration of the apparatus, the cross-flowing jet pump nozzle is positioned on a side of the clearing roller, with the cross flow jet pump nozzle spraying FSA fluid along a transverse axis of the substrate across and over surface of the substrate. Further in this different configuration, the cross-flowing jet pump nozzle is positioned at approximately a distance ranging from about 0 mm to about 30 mm away from a clearing roller's contact with the substrate along the longitudinal axis. In another embodiment, the cross-flow jet pump nozzle sprays FSA fluid across surface of the substrate along a transverse axis of the substrate. In this embodiment, the cross-flow jet pump nozzle sprays FSA fluid at an approximate nozzle exit speed between about 0.25 meters/second and about 2.5 meters/second like a straight jet stream skimming the surface of the substrate. Additionally, the cross-flow jet pump nozzle is approximately positioned at a distance from about 0 mm to about 5 mm above surface of the area to receive a substrate, within about 0 mm to 30 mm of the longitudinal edge of the substrate. In still another configuration, the FSA fluid from the cross-flow jet pump nozzle is pumped from a reservoir of fresh FSA fluid and/or pumped from circulated FSA fluid from the container.

A section of an apparatus for depositing blocks into receptor openings comprising: a container containing fluid; a dispenser positioned above an area to receive a substrate; a cross-flow jet pump nozzle to clear blocks; and a circulatory system driven by flowing fluid propelled by a pump that recycles fluid to the cross-flow jet pump nozzle and drives an ejector jet pump that replenishes the blocks and the fluid to the dispenser. In one configuration, the dispenser dispenses a slurry of blocks comprising blocks and a lubricious FSA fluid. Further, the FSA fluid may be filled to a level ranging from a point above the substrate to a point above the dispenser, submerging at least one of the substrate, the cross-flow jet pump and the dispenser below surface of the fluid. Alternately, the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. In another configuration, the substrate is a continuous sheet, at least 2 feet in length along its longitudinal axis, unrolls from one reel and rolls up into another reel and is advanced continuously along the longitudinal axis of the substrate. In a different embodiment, the ejector jet pump drives the FSA fluid at a rate approximately ranging from about 0.5 L/min to about 3 L/min. Further, the ejector jet pump propels fluid in at least one of a continuous flow, pulsating flow, and variable flow rate. In addition, the ejector jet pump is driven by fluid flow circulated from the container containing fluid through at least one of a centrifugal pump, a positive displacement pump, a gravity pump and any pump that can produce sufficient fluid flow to drive the slurry of blocks. In one embodiment, the blocks cleared from the substrate are driven into the dispenser by an ejector jet pump. In another embodiment, unused blocks from a reservoir are mixed with the blocks cleared from the substrate and driven to the dispenser by an ejector jet pump. Yet in another embodiment of the apparatus the circulatory system contains a filter. Still in another configuration, FSA fluid from the container is circulated by a pump from at least one of a drainage valve and an overflow valve into the container and the cross-flow jet pump nozzle. In yet another configuration, a pump is used to propel fluid from a FSA fluid reservoir into the cross-flow jet pump nozzle. In still another different embodiment, a dedicated pump is linked to a vacuum system for a chuck template to circulate the FSA fluid removed during vacuum suction back into the container. A section of an apparatus for depositing blocks into receptor openings comprising: a container containing fluid capable of rotation about an axis along which a substrate travels including a conduit for a substrate with the receptor openings to pass into other sections of the apparatus; a dispenser to dispense a slurry of blocks positioned over the substrate with openings; an area to receive the substrate that can be tilted to form a non-zero angle between a transverse axis of the substrate, perpendicular to the longitudinal axis in a direction of travel of the substrate, and a horizontal plane, where one longitudinal edge of the substrate is higher than another longitudinal edge when tilted; a chuck template that generates circular or any other elliptical vibration; at least one of a clearing roller rotating over surface of the substrate and a cross-flow jet pump nozzle to remove improperly positioned blocks from the surface of the substrate and the receptor openings; and a circulatory system driven by flowing fluid propelled by a pump that recycles the fluid to the cross-flow jet pump nozzle and drives an ejector jet pump that replenishes the blocks and the fluid to the dispenser. In one embodiment, one or more sections in the container comprise at least one of a block dispensing and a clearing portion of a FSA system. In another embodiment, the slurry of blocks comprises blocks and a lubricious FSA fluid. Further in this other embodiment, the FSA fluid may be filled to a level ranging from a point above the substrate to a point above the dispenser, submerging at least one of the substrate, the chuck template, the cross-flow jet pump, the clearing roller and the dispenser below surface of the fluid. Alternately, the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. In a different embodiment of the apparatus, the sheet of substrate, at least 2 feet in length along the longitudinal axis, unrolls from one reel and rolls up into another reel and is advanced continuously along the longitudinal axis at an approximate rate ranging from about 0.3 meters/min to about 10 meters/min. Moreover, the receptor openings in the substrate are formed from at least one of processes including embossing and hot-stamping. In another embodiment of the apparatus, the non-zero angle is between an approximate range of about 5 degrees and about 25 degrees. Additionally, the area to receive a substrate that is tilted have legs with adjustable height, where legs below one longitudinal edge are raised or extended to be longer than legs below another longitudinal edge. Alternatively, the area to receive the substrate that is tilted is fixed relative to the container and naturally rests in a position parallel to a horizontal plane but reaches a non-zero angle between the transverse axis and the horizontal plane by rotating the container about the longitudinal axis. In a different embodiment, the circular or any other elliptical vibrations oscillate within an approximate frequency range from about 150 Hz to about 350 Hz and within an approximate range of vibration acceleration of about 0.13 g-rms to about 1.5 g-rms with sinusoidal waveforms. Additional in this different embodiment, the substrate is positioned onto the chuck template by vacuum through openings on the chuck template, or by any other means to fix the substrate that can also be removed easily. Alternatively in this different embodiment, the circular motion is generated at least by one of a pneumatic vibrator, a pneumatic turbine vibrator, and a motor with a counterweight. Still another configuration shows that the circular or any other elliptical vibrations are controlled by at least one of excitation voltage, support bushing size and durometer, rotor size, air flow rate, and air pressure. In one embodiment of the apparatus, the substrate is positioned onto the chuck template by two rollers whose axis of rotation is parallel to a transverse axis of the substrate, each located perpendicular to and along the longitudinal axis of the substrate, just beyond the chuck template, pressing down onto the substrate over the chuck template. In another embodiment of the apparatus, the chuck template has at least one of dimples and rib template on its surface and openings for vacuum suction. Further in this other embodiment, the substrate receptor sites sit directly over the dimples and the openings for vacuum suction are located between the receptor site openings. Alternatively in this other embodiment, the rib templates on the chuck template are aligned in parallel along the longitudinal axis in a direction of substrate movement at positions of gaps between placements of the receptor openings on the chuck template and the openings for vacuum suction on the chuck template are located between the receptor opening placements and the rows of rib templates. Further in this alternate embodiment, each of the rib template may approximately rise from about 50 μm to about 2.0 mm above surface of the chuck template and the substrate may experience up to approximately 200 μm vertical deflection with a sine wave like shape or equivalent radius of curvature ranging approximately between about 15 mm and about 30 mm. In a different embodiment, the clearing roller actively rotates at a rate of approximately about 40 rpm brushing against the surface of the substrate in an opposite direction against movement of the substrate. Furthermore, the clearing roller presses onto the substrate and creates a tension in the substrate consequent of frictional forces created by opposing movement between the clearing roller and the substrate at contact. Alternately in this embodiment, the clearing roller is made of a soft material, such as PVA. Differently, the cross-flow jet pump nozzle is approximately positioned a distance of about 0 mm to about 30 mm away from the clearing roller's contact with the substrate along the longitudinal axis of the substrate. Still differently, the clearing roller has an approximate diameter of about 35 mm to about 65 mm, and an approximate length longer than the width of the wider of the chuck template and substrate, in line with the longitudinal axis of the clearing roller that is parallel to a transverse axis of the substrate and perpendicular to movement direction of the substrate. Additionally, the clearing roller is positioned away from the dispenser, along the longitudinal axis of the substrate, in direction of the moving substrate. In yet another embodiment, the cross-flow jet pump nozzle sprays FSA fluid across surface of the substrate along a transverse axis of the substrate. Further, the cross-flow jet pump nozzle sprays FSA fluid at an approximate nozzle exit speed between about 0.25 meters/second and about 2.5 meters/second like a straight jet stream skimming the surface of the substrate. Alternately, the lowest point of the inside perimeter of the cross-flow jet pump nozzle is approximately positioned about 0 mm to about 5 mm above surface of the area to receive a substrate, within about 0 mm to about 30 mm of the longitudinal edge of the substrate. In a different configuration, the FSA fluid from the cross-flow jet pump nozzle is pumped from a reservoir of fresh FSA fluid and/or pumped from circulated FSA fluid from the container. Still in another different configuration, the ejector jet pump drives the FSA fluid at a rate approximately ranging from about 0.5 L/min to about 3 L/min. Additionally, the ejector jet pump propels fluid in at least one of a continuous flow, pulsating flow, and variable flow rate. Further still, the ejector jet pump is driven by fluid flow circulated from the container containing fluid through at least one of a centrifugal pump, a positive displacement pump, a gravity pump and any pump that produces sufficient fluid flow to pump the slurry of blocks. A different configuration of the apparatus shows the blocks cleared from the substrate are driven into the dispenser by an ejector jet pump. The unused blocks from a reservoir are mixed with the blocks cleared from the substrate and driven to the dispenser by an ejector jet pump. Yet another different apparatus shows the circulatory system contains a filter. Another configuration shows FSA fluid from the container is circulated by a pump from at least one of a drainage valve and an overflow valve into the container and the cross-flow jet pump nozzle. A different configuration has a pump is used to propel fluid from a FSA fluid reservoir into the cross-flow jet pump nozzle. One other configuration has a dedicated pump is linked to a vacuum system for a chuck template to circulate the FSA fluid removed during vacuum suction back into the container. While in another configuration, the dispenser has an ejector jet pump to propel the blocks into the dispenser. Still, in a different configuration, a drying section, a lamination section, and an inspection section wherein each section is connected in series but distinctly separate from each other. Moreover, in this different configuration, the container has a round cylindrical conduit for a substrate to pass from one section of an apparatus into another section which is also rotatable about an axis to adjust the container's angle relative to a horizontal plane.

A method for depositing blocks into receptor openings comprising: aligning a substrate along a longitudinal axis in a same direction as the substrate's longest edge in a container at least partially filled with fluid; tilting an area to receive the substrate to form a non-zero angle between a transverse axis perpendicular to the longitudinal axis of the substrate and a horizontal plane; and dispensing a slurry of blocks over the area to receive the substrate from a dispenser. The slurry of blocks comprising blocks and a lubricious fluid. Additionally, the fluid may be filled to a level ranging from a point between a highest point of the tilted substrate to a point above the dispenser nozzle. Or, the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. In a different method, the substrate is a continuous sheet, at least 2 feet in length along the longitudinal axis, unrolls from one reel and rolls up into another reel and is advanced continuously along the longitudinal axis. Yet in another method, the non-zero angle is between an approximate range of about 5 degrees and about 25 degrees. Furthermore, the area to receive a substrate that is tilted have legs with adjustable height, where legs below one longitudinal edge are raised or extended to be longer than legs below another longitudinal edge. Still further, the area to receive the substrate that is tilted is fixed relative to the container and naturally rests in a position parallel to a horizontal plane but reaches a non-zero angle between the transverse axis and the horizontal plane by rotating the container about the longitudinal axis.

A method for depositing blocks into receptor openings comprising: aligning a substrate along a longitudinal axis in a same direction as the substrate's longest edge over an area to receive a substrate in a container at least partially filled with fluid; transporting the substrate over a chuck template; applying circular or any other elliptical vibrations to the substrate through a chuck template; and dispensing a slurry of blocks from a dispenser over the substrate. In this method, the slurry of blocks comprising blocks and a lubricious fluid. Furthermore, the fluid may be filled to a level ranging from a point just above the substrate to a point above the dispenser submerging at least one of the substrate, the chuck template and the dispenser. Or alternately, the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. In a different method, the substrate is a continuous sheet with receptor openings on one surface, at least 2 feet in length along its longitudinal axis, unrolls from one reel and rolls up into another reel and is advanced continuously along the longitudinal axis of the substrate and the area. Moreover, the receptor openings in the substrate are formed from at least one of processes including embossing and hot-stamping. Still, in another method, the circular or any other elliptical vibrations oscillate within an approximate frequency range from about 150 Hz to about 350 Hz and within an approximate range of vibration acceleration of about 0.13 g-rms to about 1.5 g-rms with sinusoidal waveforms. The substrate is positioned onto the chuck template by vacuum through openings on the chuck template, or by any other means to fix the substrate that can also be removed easily. Alternatively, the circular or any other elliptical vibrations are generated by at least one of a pneumatic vibrator, pneumatic turbine vibrator, and a motor with a counterweight. Still alternatively, the circular or any other elliptical vibrations are controlled by at least one of excitation voltage, support bushing size and durometer, rotor size, air flow rate, and air pressure. In yet another different method, the substrate is positioned onto the chuck template by two rollers whose axis of rotation is parallel to a transverse axis of the substrate, each located perpendicular to and along the longitudinal axis of the substrate, just beyond the chuck template, pressing down onto the substrate over the chuck template. Further, the substrate receptor sites sit directly over the dimples and the openings for vacuum suction are located between receptor site openings. Or alternatively, the rib templates on the chuck template are aligned in parallel along a longitudinal axis in a direction of substrate movement at positions of gaps between placements of the receptor openings on the chuck template and the openings for vacuum suction on the chuck template are located between the receptor opening placements and the rib templates. In addition, each of the rib template may approximately rise from about 50 μm to about 2.0 mm above surface of the chuck template and the substrate may experience up to approximately 200 μm vertical deflection with a sine wave like shape or equivalent radius of curvature approximately ranging between about 15 mm and about 30 mm.

A method for depositing blocks into receptor openings comprising: aligning a substrate along a longitudinal axis in same direction as a substrate's longest edge in a container at least partially filled with liquid; dispensing a slurry of blocks over an area to receive a substrate; and clearing improperly positioned blocks from surface of the substrate and the receptor openings using a clearing apparatus including at least one of a clearing roller and a cross-flowing jet pump nozzle. The slurry of blocks comprising blocks and a lubricious fluid. Furthermore, the fluid may be filled to a level ranging from a point above the substrate to a point above the dispenser, submerging at least one of the substrate, the cross-flow jet pump, the clearing roller and the dispenser below surface of the fluid. Alternately, the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. Still alternately, the substrate is a continuous sheet with receptor openings on one surface, at least 2 feet in length along its longitudinal axis, unrolls from one reel in one end and rolls up into another reel and is advanced continuously along the longitudinal axis of the substrate. Further alternately, the clearing roller actively rotates approximately at a rate of about 40 rpm brushing against the surface of the substrate in an opposite direction against movement of the substrate. In this last alternate form, the clearing roller presses onto the substrate and creates a tension in the substrate consequent of frictional forces created by opposing movement between the clearing roller and the substrate at contact. Still in this last alternate form, the clearing roller is made of a soft material, such as PVA foam. Further still in this last alternate form, the clearing roller has an approximate diameter of about 35 mm to about 65 mm, an approximate length longer than the width of the wider of the chuck template and substrate, in line with the longitudinal axis of the clearing roller that is parallel to a transverse axis of the substrate and perpendicular to movement direction of the substrate. Additionally, the clearing roller is positioned away from the dispenser, along the longitudinal axis of the substrate, in direction of the moving substrate. In a different method, the cross-flowing jet pump nozzle is positioned on a side of the clearing roller, with the cross flow jet pump nozzle spraying FSA fluid along a transverse axis of the substrate across and over surface of the substrate. Furthermore, the cross-flowing jet pump nozzle is positioned approximately at a distance ranging from about 0 mm to about 30 mm away from a clearing roller's contact with the substrate along the longitudinal axis. On the other hand, the FSA fluid from the cross-flow jet pump nozzle is pumped from a reservoir of fresh FSA fluid and/or pumped from circulated FSA fluid from the container. In yet another different method, the cross-flow jet pump nozzle sprays FSA fluid across surface of the substrate along a transverse axis of the substrate. In this method, the cross-flow jet pump nozzle sprays FSA fluid at an approximate nozzle exit speed between about 0.25 meters/second and about 2.5 meters/seconds like a straight jet stream skimming the surface of the substrate. Alternatively in this method, the cross-flow jet pump nozzle is approximately positioned at about 0 mm to about 5 mm above surface of the area to receive a substrate, within about 0 mm to about 30 mm of the longitudinal edge of the substrate.

A method for depositing blocks into receptor openings comprising: aligning a substrate along a longitudinal axis in a same direction as a substrate's longest edge in a container at least partially filled with fluid; dispensing a slurry of blocks from a dispenser over the substrate; and propelling the fluid by a pump in a circulatory system to recycle fluid to a cross-flow jet pump nozzle and drives an ejector jet pump that replenishes blocks and the fluid to the dispenser. The slurry of blocks comprising blocks and a lubricious fluid. Furthermore, the fluid may be filled to a level ranging from a point above the substrate to a point above the dispenser, submerging at least one of the substrate, the cross-flow jet pump and the dispenser below surface of the fluid. Or, the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. In another method, the substrate is a continuous sheet, at least 2 feet in length along its longitudinal axis, unrolls from one reel and rolls up into another reel and is advanced continuously along the longitudinal axis of the substrate. While another method has the ejector jet pump drives the FSA fluid at a rate approximately ranging from about 0.5 L/min to about 3 L/min. Additionally, the ejector jet pump propels fluid in at least one of a continuous flow, pulsating flow, and variable flow rate. Further still, the ejector jet pump is driven by fluid flow circulated from the container containing fluid through at least one of a centrifugal pump, a positive displacement pump, a gravity pump and any pump that can produce sufficient fluid flow to drive the slurry of blocks. Another different method has the blocks cleared from the substrate are driven into the dispenser by an ejector jet pump. Furthermore, unused blocks from a reservoir are mixed with the blocks cleared from the substrate and driven to the dispenser by an ejector jet pump. In one other method the circulatory system contains a filter. For another method, FSA fluid from the container is circulated by a pump from at least one of a drainage valve and an overflow valve into the container and the cross-flow jet pump nozzle. Yet another method, a pump is used to propel fluid from a FSA fluid reservoir into the cross-flow jet pump nozzle. Still, one method has a dedicated pump is linked to a vacuum system for a chuck template to circulate the FSA fluid removed during vacuum suction back into the container.

A method for depositing blocks into receptor openings in an FSA apparatus comprising: filling fluid into a portion of a container configured to rotate about a longitudinal axis along which a substrate containing receptor openings travels; aligning the substrate on the area along a longitudinal axis in the same direction as the substrate's longest edge and direction of travel; tilting an area to receive the substrate to form a non-zero angle between a transverse axis, perpendicular to the longitudinal axis of the substrate, and a horizontal plane; transporting the substrate over a chuck template; applying circular or any other elliptical vibrations to the substrate through the chuck template; dispensing a slurry of blocks over the receptor openings on the substrate; clearing improperly positioned blocks from surface of the substrate and the receptor openings using at least one of a clearing roller and a cross-flow jet pump nozzle; propelling the fluid by an ejector jet pump in a circulatory system to recycle and replenish blocks and the fluid into at least one of the dispenser and the cross-flow jet pump nozzle; and transporting the substrate containing blocks through a conduit from a first section to a second section of an FSA system. The method have a cycle of block dispensing and block clearing and the FSA apparatus comprises at least one such cycle in combination with other sections. The slurry of blocks comprises blocks and a lubricious FSA fluid. Further, the FSA fluid may be filled to a level ranging from a point above the substrate to a point above the dispenser, submerging at least one of the substrate, the chuck template, the cross-flow jet pump, the clearing roller and the dispenser below surface of the fluid. Or, the blocks are dispensed in at least one of the following forms including pressurized downward in a cyclonic motion that swirls downward from top of the dispenser to the nozzle prior to exiting the nozzle and pulled by gravity and sink from top of the dispenser to the nozzle prior to exiting the nozzle. Another method has the sheet of substrate, at least 2 feet in length along the longitudinal axis, unrolls from one reel and rolls up into another reel and is advanced continuously along the longitudinal axis at a rate approximately ranging from about 0.3 m/min to about 10 m/min. Additionally, the receptor openings in the substrate are formed from at least one of processes including embossing and hot-stamping. One other method has the non-zero angle is between an approximate range of about 5 degrees and about 25 degrees. The area to receive a substrate that is tilted have legs with adjustable height, where legs below one longitudinal edge are raised or extended to be longer than legs below another longitudinal edge. Alternately, the area to receive the substrate that is tilted is fixed relative to the container and naturally rests in a position parallel to a horizontal plane but reaches a non-zero angle between the transverse axis and the horizontal plane by rotating the container about the longitudinal axis. In another method, the circular or any other elliptical vibrations oscillate within an approximate frequency range from about 150 Hz to about 350 Hz and within an approximate range of vibration acceleration of about 0.13 g-rms to about 1.5 g-rms with sinusoidal waveforms. The substrate is positioned onto the chuck template by vacuum through openings on the chuck template, or by any other means to fix the substrate that can also be removed easily. Or, the circular motion is generated at least by one of a pneumatic vibrator, a pneumatic turbine vibrator, and a motor with a counterweight. Or further, the circular or any other elliptical vibrations are controlled by at least one of excitation voltage, support bushing size and durometer, rotor size, air flow rate, and air pressure. In one other method, the substrate is positioned onto the chuck template by two rollers whose axis of rotation is parallel to a transverse axis of the substrate, each located perpendicular to and along the longitudinal axis of the substrate, just beyond the chuck template, pressing down onto the substrate over the chuck template. Yet in another method, the chuck template has at least one of dimples and rib template on its surface and openings for vacuum suction. The substrate receptor sites sit directly over the dimples and the openings for vacuum suction are located between the receptor site openings. Alternately, the rib templates on the chuck template are aligned in parallel along the longitudinal axis in a direction of substrate movement at positions of gaps between placements of the receptor openings on the chuck template and the openings for vacuum suction on the chuck template are located between the receptor opening placements and the rows of rib templates. Furthermore in this alternate method, each of the rib template may approximately rise from about 50 μm to about 2.0 mm above surface of the chuck template and the substrate may experience up to approximately 200 μm vertical deflection with a sine wave like shape or equivalent radius of curvature approximately ranging between about 15 mm and about 30 mm. Still in another method, the clearing roller actively rotates at a rate of approximately about 40 rpm brushing against the surface of the substrate in an opposite direction against movement of the substrate. The clearing roller presses onto the substrate and creates a tension in the substrate consequent of frictional forces created by opposing movement between the clearing roller and the substrate at contact. Furthermore, the cross-flow jet pump nozzle is approximately positioned at about 0 mm to about 30 mm away from the clearing roller's contact with the substrate along the longitudinal axis of the substrate. In a slightly different form, the clearing roller is made of a soft material, such as PVA foam. Alternately, the clearing roller has an approximate diameter in the range of about 35 mm to about 65 mm, and a length longer than the width of the wider of the chuck template and substrate, in line with the longitudinal axis of the clearing roller that is parallel to a transverse axis of the substrate and perpendicular to movement direction of the substrate. Further in this alternate form, the clearing roller is positioned away from the dispenser, along the longitudinal axis of the substrate, in direction of the moving substrate. Still another method has the cross-flow jet pump nozzle sprays FSA fluid across surface of the substrate along a transverse axis of the substrate. In this method, the cross-flow jet pump nozzle sprays FSA fluid at an approximate nozzle exit speed between about 0.25 meters/second and about 2.5 meters/second like a straight jet stream skimming the surface of the substrate. Moreover, the lowest point of the inside perimeter of the cross-flow jet pump nozzle is approximately positioned at about 0 mm to about 5 mm above surface of the area to receive a substrate, within about 0 mm to about 30 mm of the longitudinal edge of the substrate. In another method, the FSA fluid from the cross-flow jet pump nozzle is pumped from a reservoir of fresh FSA fluid and/or pumped from circulated FSA fluid from the container. Still, a different method has the ejector jet pump drives the FSA fluid at a rate approximately ranging from about 0.5 L/min to about 3 L/min. Additionally, the ejector jet pump propels fluid in at least one of a continuous flow, pulsating flow, and variable flow rate. And, the ejector jet pump is driven by fluid flow circulated from the container containing fluid through at least one of a centrifugal pump, a positive displacement pump and a gravity pump that produces sufficient fluid flow to drive the slurry of blocks. In another method, the blocks cleared from the substrate are driven into the dispenser by an ejector jet pump. While unused blocks from a reservoir are mixed with the blocks cleared from the substrate and driven to the dispenser by an ejector jet pump. Further still, the circulatory system contains a filter. Yet in another method, FSA fluid from the container is circulated by a pump from at least one of a drainage valve and an overflow valve into the container and the cross-flow jet pump nozzle. In a different method, a pump is used to propel fluid from a FSA fluid reservoir into the cross-flow jet pump nozzle. Still another different method has a dedicated pump is linked to a vacuum system for a chuck template to circulate the FSA fluid removed during vacuum suction back into the container. In one other method, the dispenser has a pump to propel the blocks into the dispenser. Another method has a drying section, a lamination section, and an inspection section wherein each section is connected in series but distinctly separate from each other. Also, the container has a round cylindrical conduit for a substrate to pass from one section of an apparatus into another section which is also rotatable about an axis to adjust the container's angle relative to a horizontal plane.

An apparatus for depositing blocks into receptor openings comprising: a container containing fluid; a dispenser positioned above an area to receive a substrate; the area to receive a substrate splitting into two sections along a longitudinal axis, in a direction of travel of the substrate, each capable of an in-line tilt, forming an independent non-zero angle between the longitudinal axis and a horizontal plane, with a point between the two sections being a lowest point of the area to receive a substrate. The dispenser dispenses a slurry of blocks comprising blocks and a lubricious fluid. Besides, the fluid may be filled to a level submerging the highest point of the area receiving the substrate, including at least the dispenser. Alternately, the substrate is continuously moving along the area receiving the substrate on a decline in one section and up an incline in another section. Moreover, vibrations may be applied to the area receiving the substrate to facilitate filling blocks in the receptor openings. Or, the blocks are dispensed in a pressurized downward cyclonic motion that swirls downward from top of the dispenser to a nozzle prior to exiting the nozzle. Also in the latter form, the dispenser is located on top of a section where the substrate travels downward along a decline and is located on bottom of a section where the substrate travels upward along an incline. In a different configuration, each independent non-zero angle is between an approximate range of about 5 degrees to about 30 degrees. And, each independent non-zero angle is pivoted about a tension roller located at the lowest point between sections used to position the substrate. Further still, the in-line tilt and each independent angle is adjusted by at least one of legs with adjustable length and an acme screw below each section.

A method for depositing blocks into receptor openings comprising: aligning a substrate along a longitudinal axis in a same direction as the substrate's longest edge, over an area to receive the substrate that is split into two sections, in a container at least partially filled with fluid; tilting each section of the area to receive the substrate in-line with travel of the substrate about a pivot point, which is also a lowest point between the two sections, such that each section forms an independent non-zero angle between the longitudinal axis and a horizontal plane; and dispensing a slurry of blocks over the area to receive the substrate from a dispenser. The dispenser dispenses a slurry of blocks comprising blocks and a lubricious fluid. Further, the fluid may be filled to a level submerging the highest point of the area receiving the substrate, including at least the dispenser. In a different method, the substrate is continuously moving along the area receiving the substrate on a decline in one section and up an incline in another section. Vibrations may be applied to the area receiving the substrate to facilitate filling blocks in the receptor openings. Further, the blocks are dispensed in a pressurized downward cyclonic motion that swirls downward from top of the dispenser to a nozzle prior to exiting the nozzle. And, the dispenser is located on top of a section where the substrate travels downward along a decline and is located on bottom of a section where the substrate travels upward along an incline. Yet in another method, each independent non-zero angle is between an approximate range of about 5 degrees to about 30 degrees. Moreover, each independent non-zero angle is pivoted about a tension roller located at the lowest point between sections used to position the substrate. And, the in-line tilt and each independent angle is adjusted by at least one of legs with adjustable length and an acme screw below each section.

In the preceding detailed description, the invention is described with reference to specific embodiments thereof. It will, however be evident that various modifications and changes may be made thereto without departing from the broader spirit and scope of the invention as set forth in the claims. The specification and drawings are accordingly to be regarded in an illustrative rather than a restrictive sense.

We claim:

1. An apparatus for depositing blocks into receptor openings of a substrate comprising:
a container containing fluid;
a dispenser positioning above an area to receive the substrate; and
a chuck template having at least one of openings for vacuum suction and capability of generating at least one of circular and elliptical vibrations.

2. The apparatus as in claim 1 wherein the circular and elliptical vibrations oscillate within an approximate frequency range from about 150 Hz to about 350 Hz and within an approximate range of vibration acceleration of about 0.13 g-rms to about 1.5 g-rms with sinusoidal waveforms.

3. The apparatus as in claim 2 wherein the substrate is positioned onto the chuck template by vacuum through openings on the chuck template, or by any other means to fix the substrate that can also be removed easily.

4. The apparatus as in claim 2 wherein the circular and elliptical vibrations are generated by at least one of a pneumatic vibrator, a pneumatic turbine vibrator, and a motor with a counterweight.

5. The apparatus as in claim 2 wherein the circular and elliptical vibrations are controlled by at least one of excitation voltage, support bushing size and durometer, rotor size, air flow rate, and air pressure.

6. The apparatus as in claim 1 wherein the substrate is positioned onto the chuck template by two rollers whose axis of rotation is parallel to a transverse axis of the substrate, each located perpendicular to and along the longitudinal axis of the substrate, just beyond the chuck template, pressing down onto the substrate over the chuck template.

7. The apparatus as in claim 1 wherein the chuck template has at least one of dimples and rib template on its surface.

8. A section of an apparatus for depositing blocks into receptor openings comprising:
a container containing fluid capable of rotation about an axis along which a substrate travels including a conduit for a substrate with the receptor openings to pass into other sections of the apparatus;
a dispenser to dispense a slurry of blocks positioned over the substrate with openings;
an area to receive the substrate that can be tilted to form a non-zero angle between a transverse axis of the substrate, perpendicular to the longitudinal axis in a direction of travel of the substrate, and a horizontal plane, where one longitudinal edge of the substrate is higher than another longitudinal edge when tilted;
a chuck template that generates at least one of circular vibrations;
at least one of a clearing roller rotating over surface of the substrate and a cross-flow jet pump nozzle to remove improperly positioned blocks from the surface of the substrate and the receptor openings; and
a circulatory system driven by flowing fluid propelled by a pump that recycles the fluid to the cross-flow jet pump nozzle and drives an ejector jet pump that replenishes the blocks and the fluid to the dispenser.

9. The section of an apparatus as in claim 8 wherein the circular vibrations oscillate within an approximate frequency range from about 150 Hz to about 350 Hz and within an approximate range of vibration acceleration of about 0.13 g-rms to about 1.5 g-rms with sinusoidal waveforms.

10. The section of an apparatus as in claim 9 wherein the substrate is positioned onto the chuck template by vacuum through openings on the chuck template, or by any other means to fix the substrate that can also be removed easily.

11. The section of an apparatus as in claim 9 wherein the circular motion is generated at least by one of a pneumatic vibrator, a pneumatic turbine vibrator, and a motor with a counterweight.

12. The section of an apparatus as in claim 9 wherein the circular vibrations are controlled by at least one of excitation voltage, support bushing size and durometer, rotor size, air flow rate, and air pressure.

13. A method for depositing blocks into receptor openings comprising:
aligning a substrate along a longitudinal axis in a same direction as the substrate's longest edge over an area to receive a substrate in a container at least partially filled with fluid;
transporting the substrate over a chuck template;
applying at least one of circular and elliptical vibrations to the substrate through a chuck template; and
dispensing a slurry of blocks from a dispenser over the substrate.

14. The method as in claim 13 wherein the circular and elliptical vibrations oscillate within an approximate frequency range from about 150 Hz to about 350 Hz and within an approximate range of vibration acceleration of about 0.13 g-rms to about 1.5 g-rms with sinusoidal waveforms.

15. The method as in claim 14 wherein the substrate is positioned onto the chuck template by vacuum through openings on the chuck template, or by any other means to fix the substrate that can also be removed easily.

16. The method as in claim 14 wherein the circular and elliptical vibrations are generated by at least one of a pneumatic vibrator, pneumatic turbine vibrator, and a motor with a counterweight.

17. The method as in claim 14 wherein the circular and elliptical vibrations are controlled by at least one of excitation voltage, support bushing size and durometer, rotor size, air flow rate, and air pressure.

18. A method for depositing blocks into receptor openings in an FSA apparatus comprising:
filling fluid into a portion of a container configured to rotate about a longitudinal axis along which a substrate containing receptor openings travels;
aligning the substrate on the area along a longitudinal axis in the same direction as the substrate's longest edge and direction of travel;
tilting an area to receive the substrate to form a non-zero angle between a transverse axis, perpendicular to the longitudinal axis of the substrate, and a horizontal plane;
transporting the substrate over a chuck template;
applying circular vibrations to the substrate through the chuck template;
dispensing a slurry of blocks over the receptor openings on the substrate;
clearing improperly positioned blocks from surface of the substrate and the receptor openings using at least one of a clearing roller and a cross-flow jet pump nozzle;
propelling the fluid by an ejector jet pump in a circulatory system to recycle and replenish blocks and the fluid into at least one of the dispenser and the cross-flow jet pump nozzle; and
transporting the substrate containing blocks through a conduit from a first section to a second section of an FSA system.

19. The method as in claim 18 wherein the circular vibrations oscillate within an approximate frequency range from about 150 Hz to about 350 Hz and within an approximate range of vibration acceleration of about 0.13 g-rms to about 1.5 g-rms with sinusoidal waveforms.

20. The method as in claim 19 wherein the substrate is positioned onto the chuck template by vacuum through openings on the chuck template, or by any other means to fix the substrate that can also be removed easily.

21. The method as in claim 19 wherein the circular motion is generated at least by one of a pneumatic vibrator, a pneumatic turbine vibrator, and a motor with a counterweight.

22. The method as in claim 19 wherein the circular vibrations are controlled by at least one of excitation voltage, support bushing size and durometer, rotor size, air flow rate, and air pressure.
